(19) United States
(12) Patent Application Publication
(10) Pub. No.: US 2010/0001174 A1
(43) Pub. Date: Jan. 7, 2010

(54) SEMICONDUCTOR DEVICE, ITS MANUFACTURING METHOD AND OPTICAL PICKUP MODULE

(76) Inventors: Junya Furuyashiki, Kagoshima (JP); Syouzuo Moribe, Kagoshima (JP); Hiroki Utatsu, Kagoshima (JP); Noriyuki Yoshikawa, Osaka (JP); Toshiyuki Fukuda, Kyoto (JP); Masanori Minamio, Osaka (JP); Hiroyuki Ishida, Osaka (JP)

Correspondence Address: MCDERMOTT WILL & EMERY LLP, 600 13TH STREET, NW, WASHINGTON, DC, 20005-3096, US

(21) Appl. No.: 12/525,499

(22) PCT Filed: Mar. 10, 2008
(86) PCT No.: PCT/JP2008/000512

§ 371 Date: Jul. 31, 2009

(30) Foreign Application Priority Data
Mar. 14, 2007 (JP) 2007-064795

(51) Int. Cl. H01J 3/14; H01L 23/00; H01L 21/78

(52) U.S. Cl. 250/216; 257/678; 438/113; 257/E23.002; 257/E21.599

(57) ABSTRACT

In a semiconductor device, a semiconductor element is mounted on a substantially rectangular package. First ribs are respectively provided on a pair of opposite external edges of a mounting surface and project upward from the pair of opposite external edges. External edges of a lid are placed on the upper surfaces of the first ribs, and fixed thereto with an adhesive. Dams are provided on external edges of the first rib upper surfaces. The adhesive is continuously present from side surfaces of the lid to the dams.

### TECHNICAL FIELD

The present invention relates to semiconductor devices, methods for fabricating the devices, and optical pickup modules.

### BACKGROUND ART

Conventional optical disk drives for reading signals from optical disks such as DVDs are provided with optical pickup modules in each of which a semiconductor laser for emitting light for reading, and a photodetector for receiving feedback light reflected from optical disks are mounted on the same base.

As disclosed in Patent Document 1, an optical disk drive includes an optical pickup module located under the optical recording surface of an optical disk and configured to move along the radius of the optical disk. Because of this configuration, size reduction of the optical disk drive requires miniaturization of the optical pickup module, which further requires miniaturization of the photodetector.

For example, Patent Document 2 discloses a method for fabricating a solid-state imaging device. This method is intended for miniaturization of a photodetector by reducing the size of a housing for accommodating a solid-state imaging element. Specifically, the method includes: resin-molding a housing including a base and rectangular frame-shaped ribs in one piece with a plurality of metal lead pieces, forming internal terminal portions and external terminal portions with the metal lead pieces; fixing an imaging element onto the base inside an internal space of the housing; connecting electrodes of the imaging element respectively to the inner terminal portions of the metal lead pieces; and fixing a transparent plate to an upper face of the ribs. In this method, in order to locate the transparent plate, a stepped portion is formed on the top face of the ribs, providing a lower step that is lowered along an internal periphery, the transparent plate has a size capable of being mounted onto an upper surface of the lower step within a region inward of an inner wall formed by the stepped portion of the ribs, and when fixing the transparent plate to the upper face of the ribs, an adhesive is provided on the upper face of the lower step, then the transparent plate is placed on the adhesive to be fixed to the upper surface of the lower step while regulating its position with the inner wall of the stepped portion, and then the portion positioned outside the stepped portion of the ribs is removed.

### Patent Document 1: Japanese Laid-Open Patent Publication No. 2001-56950

### Patent Document 2: Japanese Laid-Open Patent Publication No. 2005-64292

### Patent Document 3: Japanese Laid-Open Patent Publication No. 2005-79537

### DISCLOSURE OF INVENTION

### Problems that the Invention is to Solve

However, as illustrated in FIG. 32, in the solid-state imaging device disclosed in Patent Document 2, rectangular frame-shaped ribs 203 are provided on the external edges of a base 202 onto which an imaging element 205 is mounted. The four sides of the rectangular ribs 203 have an identical width, and thus miniaturization has limitations. The solid-state imaging device disclosed in Patent Document 3 has similar drawbacks.

It is therefore an object of the present invention to provide a semiconductor device which can be reduced in overall size, particularly in the length of a pair of two opposite sides out of the four sides of a substantially rectangular package.

### Means of Solving the Problems

To achieve the object, according to the present invention, a package with a new configuration has been devised for a semiconductor device including a semiconductor element and a package on which the semiconductor element is mounted.

Specifically, in a first semiconductor device according to the present invention, the package includes a base which is substantially rectangular and has a mounting surface on which the semiconductor element is mounted and first ribs respectively provided only on a pair of opposite external edges of the mounting surface and extending along the pair of opposite external edges, a dam is provided on an upper surface of each of the first ribs, and extends along an external edge of the upper surface of the first rib, an external edge portion of a lid covering the semiconductor element is placed on the upper surface of each of the first ribs, and is at a location separated from the dam and closer to the semiconductor element than the dam, and the lid is bonded to the first ribs with an adhesive which is sandwiched between the lid and the dam.

In a second semiconductor device according to the present invention, the package includes a base which is substantially rectangular and has a mounting surface on which the semiconductor element is mounted, first ribs respectively provided on a pair of opposite external edges of the mounting surface and extending along the pair of opposite external edges, and second ribs respectively provided on another pair of opposite external edges of the mounting surface and extending along the another pair of opposite external edges, a dam is provided on an upper surface of each of the first ribs, and extends along an external edge of the upper surface of the first rib, an external edge portion of a lid covering the semiconductor element is placed on the upper surface of each of the first ribs, and is at a location separated from the dam and closer to the semiconductor element than the dam, the lid is bonded to the first ribs with an adhesive which is sandwiched between the lid and the dam, and a width of each of the second ribs orthogonal to the another pair of opposite external edges is smaller than a width of each of the first ribs orthogonal to the pair of external edges.

The lid may be bonded to the second ribs with the adhesive.

The adhesive preferably also adheres to a side surface of the lid facing the dam.

A side wall surface of each of the first ribs along the external edge of the mounting surface on which the first rib is provided may be flush with an external side wall surface of the dam along the external edge of the upper surface of the first rib.

In a third semiconductor device according to the present invention, the package includes a base which is substantially rectangular and has a mounting surface on which the semiconductor element is mounted and first ribs respectively provided only on a pair of opposite external edges of the mounting surface and extending along the pair of opposite external edges, an external edge portion of a lid covering the semiconductor element is placed on an upper surface of each of the first ribs, the lids is bonded to the first ribs with an adhesive, a fillet is formed of the adhesive on a side surface of the lid located on each of the first ribs, and a trace of blockage remains at an end of the fillet opposite an end of the fillet facing the side surface of the lid. The fillet herein refers to a narrow strip adhering to both the side surface of the lid and the upper surface of the first rib.

In a fourth semiconductor device according to the present invention, the package includes a base which is substantially rectangular and has a mounting surface on which the semiconductor element is mounted, first ribs respectively provided on a pair of opposite external edges of the mounting surface and extending along the pair of opposite external edges, second ribs respectively provided on another pair of opposite external edges of the mounting surface and extending along the another pair of opposite external edges, an external edge portion of a lid covering the semiconductor element is placed on an upper surface of each of the first ribs, the lids is bonded to the first ribs with an adhesive, a fillet is formed of the adhesive on a side surface of the lid located on each of the first ribs, a trace of blockage remains at an end of the fillet opposite an end of the fillet facing the side surface of the lid, and a width of each of the second ribs orthogonal to the another pair of opposite external edges is smaller than a width of each of the first ribs orthogonal to the pair of external edges.

The lid may be bonded to the second ribs with the adhesive.

A first method for fabricating a semiconductor device according to the present invention is a method for fabricating a semiconductor device including a semiconductor element and a package on which the semiconductor element is mounted. The first method includes the steps of preparing a package-assembled board including a plurality of parallel trenches, and dams respectively located on middle portions of upper surfaces of side walls of the trenches and extending along the trenches, placing a plurality of semiconductor elements in each of the trenches in a direction along which the trench extends; continuously applying an adhesive, along the trenches, onto portions of the upper surfaces of the side walls of the trenches located between the dams and the trenches, X: placing an external edge portion of a lid on the adhesive such that the lid covers each of the semiconductor elements, hardening the adhesive, and Y: cutting, along the trenches, the package-assembled board at a middle portion thereof between each adjacent two of the trenches, thereby dividing the package-assembled board.

A second method for fabricating a semiconductor device according to the present invention is a method for fabricating a semiconductor device including a semiconductor element and a package on which the semiconductor element is mounted. The second method includes the steps of: preparing a package-assembled board including a plurality of recesses arranged in rows and columns, and dams respectively located on middle portions between adjacent rows of the recesses and extending along the rows; placing a plurality of semiconductor elements in each of the recesses; continuously applying an adhesive, along the dams, onto portions between the rows of the recesses and neighboring the dams; X: placing an external edge portion of a lid on the adhesive such that the lid covers each of the semiconductor elements; hardening the adhesive; and Z: cutting the package-assembled board at a middle portion thereof between each adjacent two of the recesses along the rows of the recesses, thereby dividing the package-assembled board.

A distance between each adjacent columns of the recesses is preferably smaller than or equal to a distance between each adjacent rows of the recesses.

In step Y or Z, parts of the dams may also be cut.

In step X, the adhesive preferably adheres to a side surface of the lid, and forms a fillet.

An optical pickup module according to the present invention includes: one of the semiconductor devices described above; a laser module; and a beam splitter, wherein the lid is made of a transparent material, and the semiconductor element included in the semiconductor device is a photoreceiver.

The optical pickup module preferably further includes a mirror and an objective lens. Preferably, the optical pickup module is placed under an information-recording surface of an optical disk, and a direction along which the ribs extend is substantially perpendicular to the information-recording surface.

The laser module preferably includes: a blue-violet laser device configured to emit light having a peak wavelength ranging from 385 nm to 425 nm, both inclusive; and a dual-wavelength laser device configured to emit light having a peak wavelength ranging from 630 nm to 670 nm, both inclusive, and light having a peak wavelength ranging from 760 nm to 800 nm, both inclusive. The peak wavelength of emitted light is a wavelength at which the intensity is at the maximum in a spectrum of the light.

### EFFECTS OF THE INVENTION

In a semiconductor device according to the present invention, a lid is bonded to the upper surfaces of a pair of opposing first ribs, and a pair of opposing second ribs has a width smaller than that of the first ribs, or no second ribs are provided. Accordingly, the overall size can be reduced. In addition, dams of an adhesive are provided on the upper surfaces of the first ribs, and thus it is possible to prevent the adhesive from extending out. The dams may be removed after hardening of the adhesive.

### BRIEF DESCRIPTION OF DRAWINGS

FIG. 1(a) is a view, partially broken away, illustrating a semiconductor device according to a first embodiment. FIG. 1(b) is a view of the bottom in FIG. 1(a).

FIG. 2(a) is a top view illustrating the semiconductor device of the first embodiment with a lid removed. FIG. 2(b) is a cross-sectional view taken along line A-A′ in FIG. 2(a). FIG. 2(c) is a cross-sectional view taken along line B-B′ in FIG. 2(a).

FIG. 3 shows fabrication of the semiconductor device of the first embodiment in chronological order.

FIG. 4 is a partial top view corresponding to FIG. 3(c).

FIG. 5 is a view illustrating another example of a package-assembled board according to the first embodiment.

FIG. 6(a) is a view, partially broken away, illustrating a semiconductor device according to a second embodiment. FIG. 6(b) is a view of the bottom in FIG. 6(a).

FIG. 7 shows fabrication of the semiconductor device of the second embodiment in chronological order.

FIG. 8(a) is a view, partially broken away, illustrating a semiconductor device according to a third embodiment. FIG. 8(b) is a view of the bottom in FIG. 8(a).

FIG. 9(a) is a top view illustrating the semiconductor device of the third embodiment with a lid removed. FIG. 9(b) is a cross-sectional view taken along line A-A′ in FIG. 9(a). FIG. 9(c) is a cross-sectional view taken along line B-B′ in FIG. 9(a).

FIG. 10 illustrates examples of a lattice member.

FIG. 11 illustrates other examples of the lattice member.

FIG. 12(a) is a view, partially broken away, illustrating a semiconductor device according to a fourth embodiment. FIG. 12(b) is a view of the bottom in FIG. 12(a).

FIG. 13(a) is a view, partially broken away, illustrating a semiconductor device according to a fifth embodiment. FIG. 13(b) is a view of the bottom in FIG. 13(a).

FIG. 14(a) is a top view illustrating the semiconductor device of the fifth embodiment with a lid removed. FIG. 14(b) is a cross-sectional view taken along line A-A′ in FIG. 14(a). FIG. 14(c) is a cross-sectional view taken along line B-B′ in FIG. 14(a).

FIG. 15 is a view partially illustrating the upper surface at a point of time in fabrication of the semiconductor device of the fifth embodiment.

FIG. 16 is a view partially illustrating the upper surface at another point of time in fabrication of the semiconductor device of the fifth embodiment.

FIG. 17(a) is a view, partially broken away, illustrating a semiconductor device according to a sixth embodiment. FIG. 17(b) is a view of the bottom in FIG. 17(a).

FIG. 18(a) is a perspective view illustrating a semiconductor device according to a first reference embodiment. FIG. 18(b) is a view of the bottom in FIG. 18(a).

FIG. 19(a) is a top view illustrating the semiconductor device of the first reference embodiment with an encapsulating resin omitted. FIG. 19(b) is a cross-sectional view taken along line A-A′ in FIG. 19(a). FIG. 19(c) is a cross-sectional view taken along line B-B′ in FIG. 19(a).

FIG. 20 shows fabrication of the semiconductor device of the first reference embodiment in chronological order.

FIG. 21 shows cross sections of other semiconductor devices according to the first reference embodiment.

FIG. 22(a) is a perspective view illustrating a semiconductor device according to a second reference embodiment. FIG. 22(b) is a view of the bottom in FIG. 22(a).

FIG. 23(a) is a perspective view illustrating a semiconductor device according to a third reference embodiment. FIG. 23(b) is a view of the bottom in FIG. 23(a).

FIG. 24(a) is a top view illustrating the semiconductor device of the third reference embodiment with an encapsulating resin omitted. FIG. 24(b) is a cross-sectional view taken along line A-A′ in FIG. 24(a). FIG. 24(c) is a cross-sectional view taken along line B-B′ in FIG. 24(a).

FIG. 25(a) is a perspective view illustrating a semiconductor device according to a fourth reference embodiment. FIG. 25(b) is a view of the bottom in FIG. 25(a).

FIG. 26(a) is a view, partially broken away, illustrating a semiconductor device according to a seventh embodiment. FIG. 26(b) is a view of the bottom in FIG. 26(a).

FIG. 27(a) is a top view illustrating the semiconductor device of the seventh embodiment with a lid removed. FIG. 27(b) is a cross-sectional view taken along line B-B′ in FIG. 27(a). FIG. 27(c) is a cross-sectional view taken along line A-A′ in FIG. 27(a).

FIG. 28(a) is a view, partially broken away, illustrating a semiconductor device according to an eighth embodiment. FIG. 28(b) is a cross-sectional view taken along line B-B′ in FIG. 28(a).

FIG. 29(a) is a view, partially broken away, illustrating a semiconductor device according to a ninth embodiment. FIG. 29(b) is a cross-sectional view taken along line B-B′ in FIG. 29(a).

FIG. 30 is a perspective view schematically illustrating an optical pickup module according to the first embodiment.

FIG. 31 is a front view schematically illustrating an optical pickup module according to the first embodiment.

FIG. 32 is a top view illustrating a conventional semiconductor device including a photoreceiver.

### DESCRIPTION OF SYMBOLS

1, 2, 3, 4, 5, 6 semiconductor device
1′, 3, 5′ semiconductor device
10 semiconductor element
22 metal wire
30 plate-like side wall
41 first laser device
42 second laser device
43 beam splitter
45 mirror
46 objective lens
47 optical disk
49 laser module
50, 51, 52, 53 package
60, 60′ base
62, 62′ mounting surface
64, 64′ non-mounting surface
70,70′ first rib
70a, 70a′ first rib external side wall surface
70b, 70b′ first rib upper surface
70, 71′ second rib
75, 75′ connection electrode
76, 76′ internal interconnection
77 external-connection portion
80, 80′ dam
80a dam external side wall surface
85 adhesive
90, 91 lid
90a lid side wall surface
94, 94a, 95 transparent member
96 encapsulating resin
100, 101, 102 package-assembled board

### BEST MODE FOR CARRYING OUT THE INVENTION

Hereinafter, embodiments of the present invention will be specifically described with reference to the drawings. In the drawings, components having substantially the same functions are denoted by the same reference character for simplicity of description.

### Embodiment 1

### —Semiconductor Device—

A semiconductor device according to a first embodiment is a photodetector employing an integrated photoreceiver as a semiconductor element. The semiconductor element may be a photoreceiver such as a photodiode, a phototransistor, and a photo IC, or a light-emitting element such as an LED and a semiconductor laser.

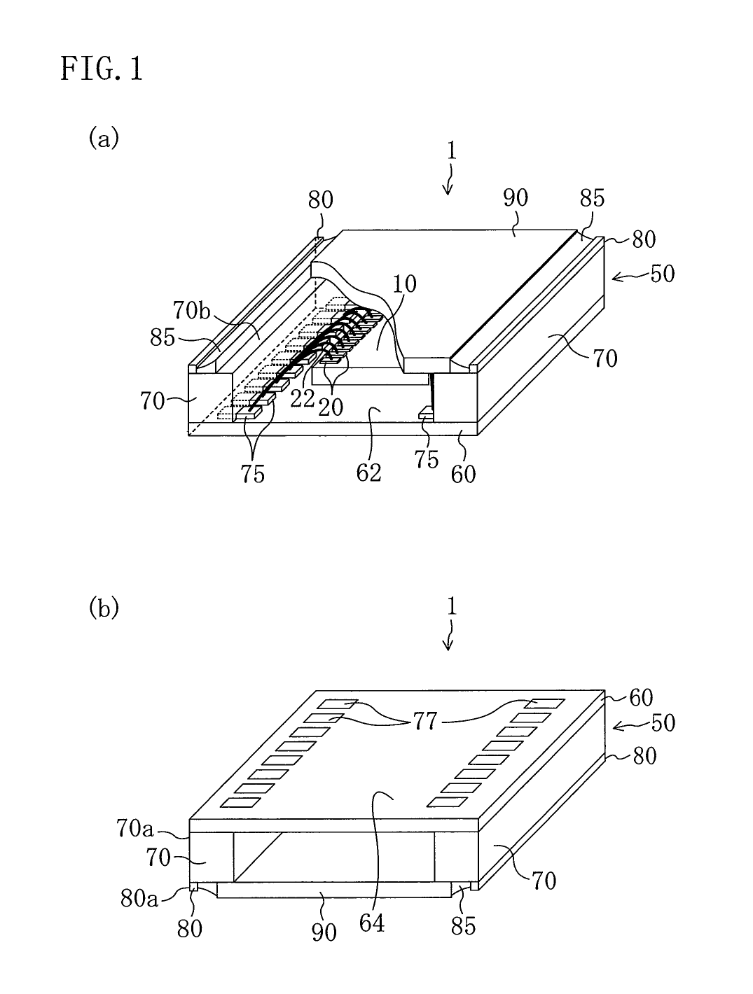

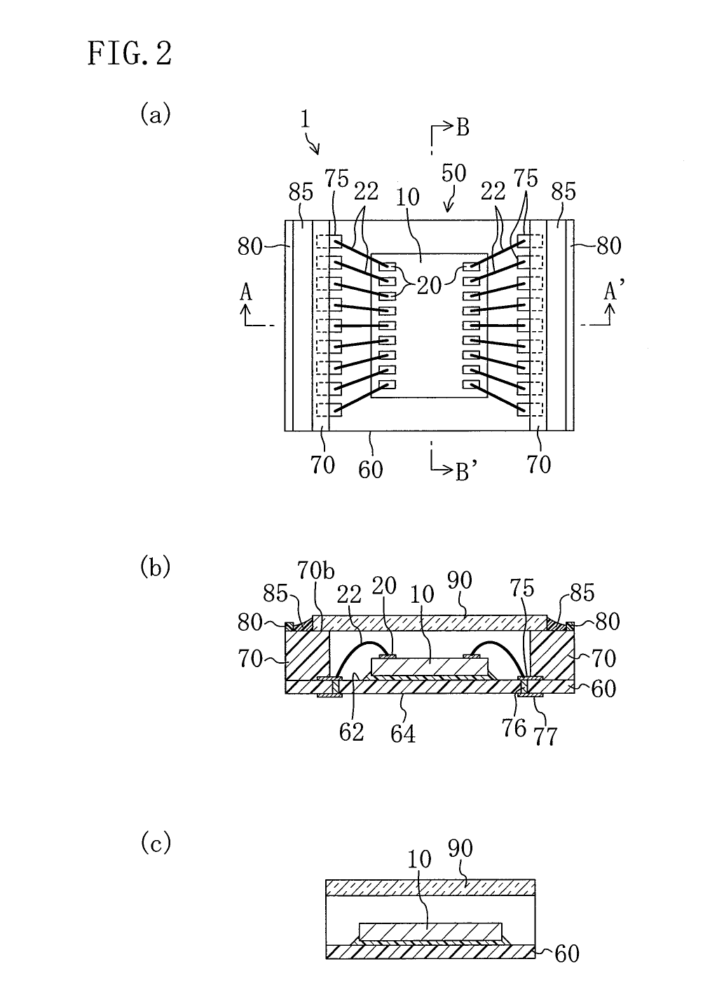

Specifically, as illustrated in FIG. 1, in a semiconductor device 1 of this embodiment, a semiconductor element 10 is housed in a recess of a recessed package 50 having a “U” shape in cross section, and a transparent flat lid 90 covers the recess. FIGS. 2(a) through 2(c) also illustrate the semiconductor device 1 of this embodiment. In FIG. 2(a), the lid 90removed and is not shown for convenience of description.

The package 50 of this embodiment includes: a rectangular base 60; two first ribs 70, 70 projecting upward from the base 60 and respectively extending along a pair of opposite sides of the rectangle; and dams 80, 80 respectively provided at the external edges of the first rib upper surfaces 70b. The first ribs 70, 70 are respectively provided only on a pair of opposite external edges of a rectangular mounting surface 62 of the base 60 on which the semiconductor element 10 is mounted. Each of the first ribs 70, 70 is in the shape of a rectangular solid extending along an associated one of the external edges of the mounting surface 62. The phrase “the first ribs 70, 70 are provided only on a pair of opposite external edges” means that the first ribs 70, 70 are provided on the above-mentioned pair of external edges but are not provided on another pair of opposite external edges of the mounting surface 62 and on a center portion and its periphery of the mounting surface 62.

On the mounting surface 62, a plurality of connection electrodes 75, 75, . . . are aligned between the mounted semiconductor element 10 and each of the first ribs 70. Each of the connection electrodes 75 extends to a portion under an associated one of the first ribs 70, and is partially hidden under the first rib 70. The connection electrodes 75 are connected to buried electrodes 76, 76, . . . provided in the base 60. A plurality of external-connection portions 77, 77, . . . are provided on a non-mounting surface 64 of the base 60 opposite the mounting surface 62, and are connected to the buried electrodes 76, 76, . . . . That is, the connection electrodes 75, 75, . . . are electrically connected to the external-connection portions 77, 77, . . . via the buried electrodes 76, 76, . . . .

The semiconductor element 10 is rectangular, and a plurality of electrode pads 20, 20, . . . are aligned along each of a pair of two opposite sides of the semiconductor element 10 on a surface of the semiconductor element 10. The surface of the semiconductor element 10 opposite the surface on which the electrode pads 20, 20, . . . are provided is placed on the mounting surface 62, and is fixed to the mounting surface 62 with an adhesive. With this configuration, the semiconductor element 10 is mounted on the package 50 in such a manner that the electrode pads 20, 20, . . . are arranged in lines substantially in parallel with the direction along which the first ribs 70, 70 extend. The electrode pads 20, 20, . . . are connected to the connection electrodes 75, 75, . . . by metal wires 22, 22, . . . .

The dams 80, 80 are located farthest from the semiconductor element 10 on the first rib upper surfaces 70b, and extend along the direction in which the first ribs 70, 70 extend. External edge portions of a rectangular lid 90 are respectively placed on the first rib upper surfaces 70b at locations away from the dams 80, 80, and are fixed with an adhesive 85. The adhesive 85 is sandwiched between the lower surfaces of the external edge portions of the lid 90 and the first rib upper surfaces 70b, and is also sandwiched between the dams 80 and side surfaces of the lid 90. The portions of the adhesive 85 located between the first rib upper surfaces 70b and the lid 90 are thin, and thus are not shown in FIG. 2(a). In the same manner, these portions are not shown in cross-sectional views for the second and subsequent embodiments.

Since the adhesive 85 is sandwiched between the dams 80 and the side surfaces of the lid 90, the lid 90 is more firmly fixed to the first ribs 70 than in a configuration where the adhesive 85 is sandwiched only between the lower surfaces of the external edge portions of the lid 90 and the first rib upper surfaces 70b. In particular, in this embodiment, portions of the adhesive 85 sandwiched between the dams 80 and the side surfaces of the lid 90 form fillets at the corners formed by the side surfaces of the lid 90 and the first rib upper surfaces 70b, thus more firmly fixing the lid 90 to the first ribs 70 even with a small amount of the adhesive 85.

In addition, a first rib external side wall surface 70a and a dam external side surface 80a are flush with each other at each side wall surface of the semiconductor device 1. This structure can reduce the length of each side of the semiconductor device 1 between the first ribs 70, 70, thus contributing to miniaturization. Moreover, the extension of the adhesive 85 is blocked by the dams 80, and thus the adhesive 85 does not extend out from the side wall surfaces of the semiconductor device 1. The “external side wall surfaces” herein refer to the side wall surfaces of the first ribs 70, 70 and the dams 80, 80 opposite the side wall surfaces thereof facing the semiconductor element 10.

In this embodiment, no ribs are provided on a pair of opposite external edges of the base 60 different from the pair of opposite external edges on which the first ribs 70, 70 are provided. Thus, the distance between the pair of opposite external edges on which no ribs are provided is determined according to the size of the semiconductor element 10 and the area necessary for arranging the connection electrodes 75, 75, . . . That is, the distance between the pair of opposite external edges with no ribs can be minimized in a package on which the semiconductor element 10 is mounted.

### —Method for Fabricating Semiconductor Device—

A method for fabricating a semiconductor device 1 according to this embodiment is now described.

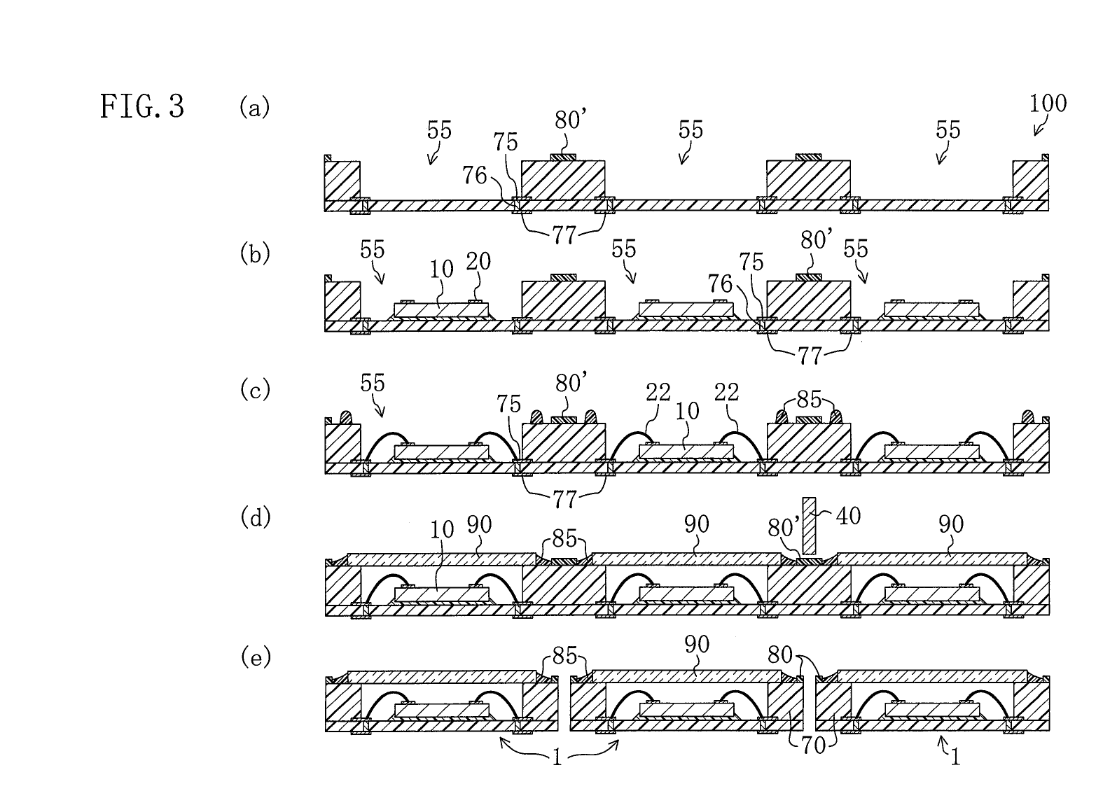

First, a package-assembled board 100 illustrated in FIG. 3(a) is prepared. In the package-assembled board 100, a plurality of packages 50 as described above are arranged, and first rib external side wall surfaces 70a of adjacent ones of the packages 50 are united. Along the direction in which the ribs extend, a plurality of packages 50 are also arranged and united.

This package-assembled board 100 can be fabricated by a known method. For example, a plurality of through holes are formed in parallel lines in a flat board. A conductor is buried in these through holes to form buried electrodes 76, 76, . . . . Connecting electrodes 75, 75, . . . connected to the buried electrodes 76, 76, . . . are formed on the upper surface of the board, whereas external-connection portions 77, 77, . . . are formed on the lower surface of the board. Then, first rib prototypes 70′, 70!, . . . in the shape of quadrangular prisms are provided on the connection electrodes 75, 75, . . . and fixed thereto in such a manner that each of the first rib prototypes 70′ is located on a pair of adjacent two lines of the connection electrodes 75, 75 . . . with a trench 55 left between the pairs of adjacent two lines of the connection electrodes 75, 75, . . . . Thereafter, dams 80′ are respectively placed on middle portions of the upper surfaces of the first rib prototypes 70′. In this manner, a package-assembled board 100 is obtained. The dams 80′ extend in parallel with the trenches 55.

Next, a plurality of semiconductor elements 10 are mounted on, and fixed to, each of the bottom surfaces of the trenches 55, 55, 55 along the direction in which the trenches 55, 55, 55 extend. This state is illustrated in FIG. 3(b).

Then, electrode pads 20 of the semiconductor elements 10 are wire bonded to the connection electrodes 75. Subsequently, an adhesive 85 is continuously applied, along the trenches 55, onto portions of the upper surfaces of the first rib prototypes 70′ located between the dams 80′ and the trenches 55. In this manner, as illustrated in FIG. 3(c), the electrode pads 20 and the connection electrodes 75 are connected by metal wires 22, and the adhesive 85 is located on the upper surfaces of the first rib prototypes 70′.

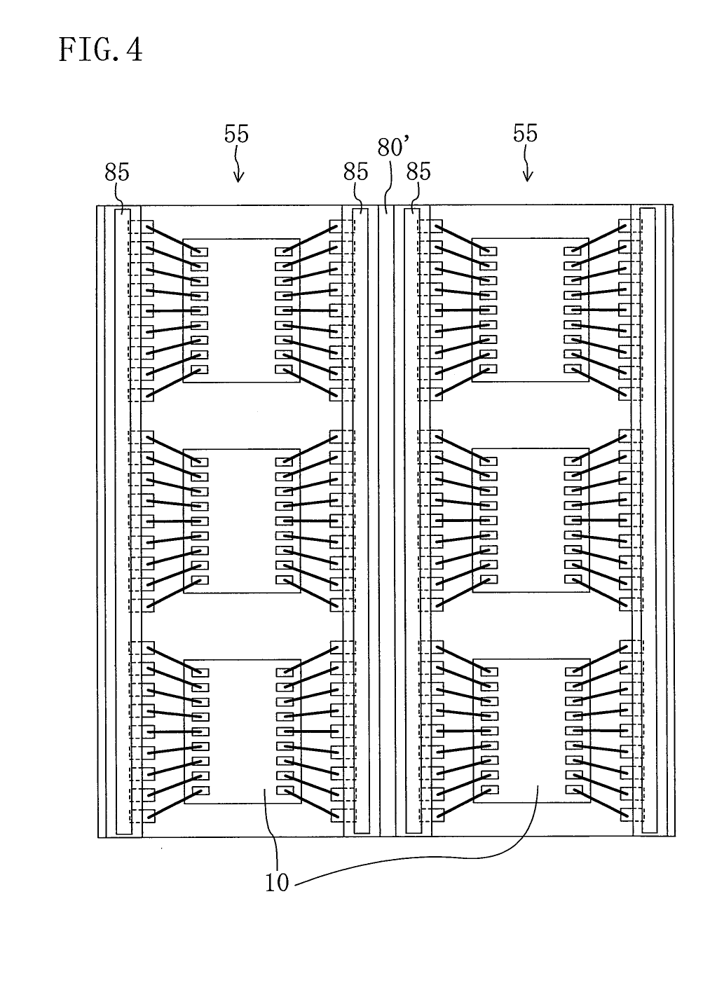

The continuous application of the adhesive 85 described above means that the adhesive 85 is applied in a line along the dams 80′ without interruption at portions corresponding to boundaries between adjacent semiconductor elements, as illustrated in FIG. 4.

Thereafter, transparent lids 90 for the respective semiconductor elements 10 are placed on the package-assembled board 100 in such a manner that external edge portions of the lids 90 are located on the adhesive 85. The lids 90 cover the respective semiconductor elements 10. Then, the adhesive 85 is hardened, thereby bonding and fixing the lids 90. This state is shown in FIG. 3(d). At this time, each of the external edges of the lids 90 is located on approximately a half of the applied adhesive 85, and thus the adhesive 85 is not only located between the bottom surfaces of the lids 90 and the upper surfaces of the first rib prototypes 70′ but also adheres to the side surfaces of the lids 90, and is extruded toward the dams 80′. However, the dams 80′ block the extrusion of the adhesive 85 and prevent the adhesive 85 from extending out to the adjacent package regions. At the same time, the adhesive 85 forms fillets which adhere to the side surfaces of the lids 90 and become thinner toward the dams 80′.

Subsequently, the package-assembled board 100 is cut into two with a dicing saw 40 at middle portions of the dams 80′ between adjacent two of the trenches 55, 55. In this manner, the side wall surfaces become flush with one another. Then, adjacent ones of the semiconductor elements 10 arranged perpendicularly to the direction along which the trenches 55 extend are separated from each other by cutting. The state after the separation is shown in FIG. 3(e). In this manner, individual semiconductor devices 1 are obtained.

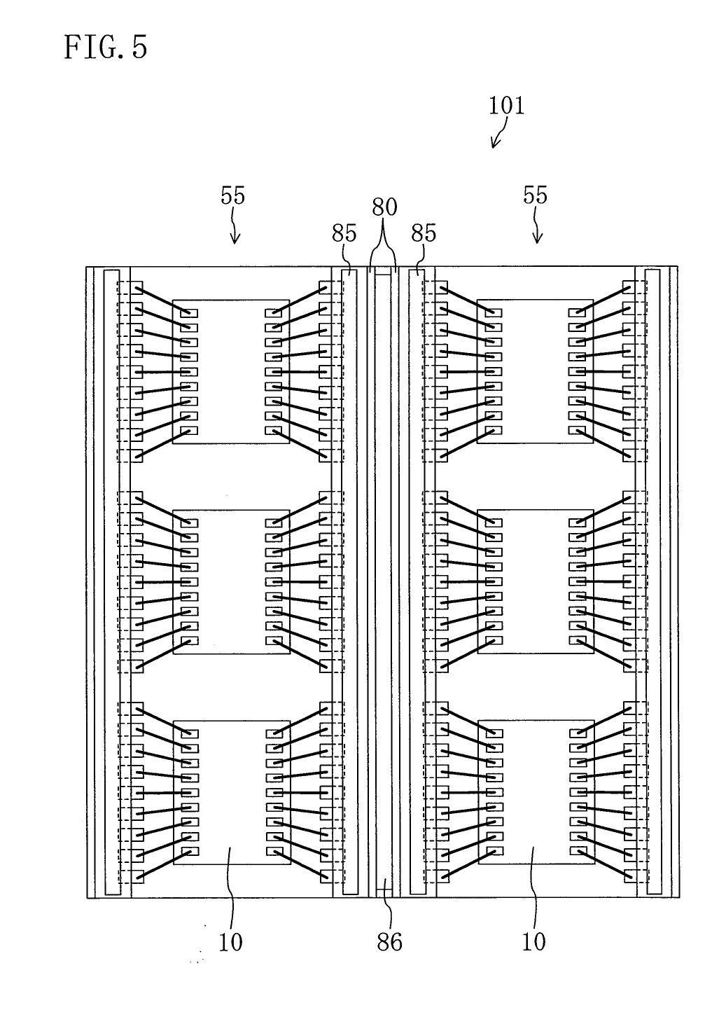

The above-described method for fabricating semiconductor devices 1 is merely an example, and the fabrication method of this embodiment is not limited to this example. The lids 90 may be placed after the separation of the adjacent trenches 55, 55. The trenches 55 are not necessarily formed by providing the first rib prototypes on the board, and may be formed by cutting a thick board or by using laser light. Alternatively, as illustrated in FIG. 5, a package-assembled board 101 in which a slit 86 is provided between adjacent trenches 55, 55 may be used. In this case, such a configuration prevents warping or deforming of the package-assembled board 101 even with an increase (in the area) of the package-assembled board 101, and allows the trenches 55, 55 to be very easily separated with the dicing saw 40 for a short period of time, resulting in easy processing.

### —Optical Pickup Module—

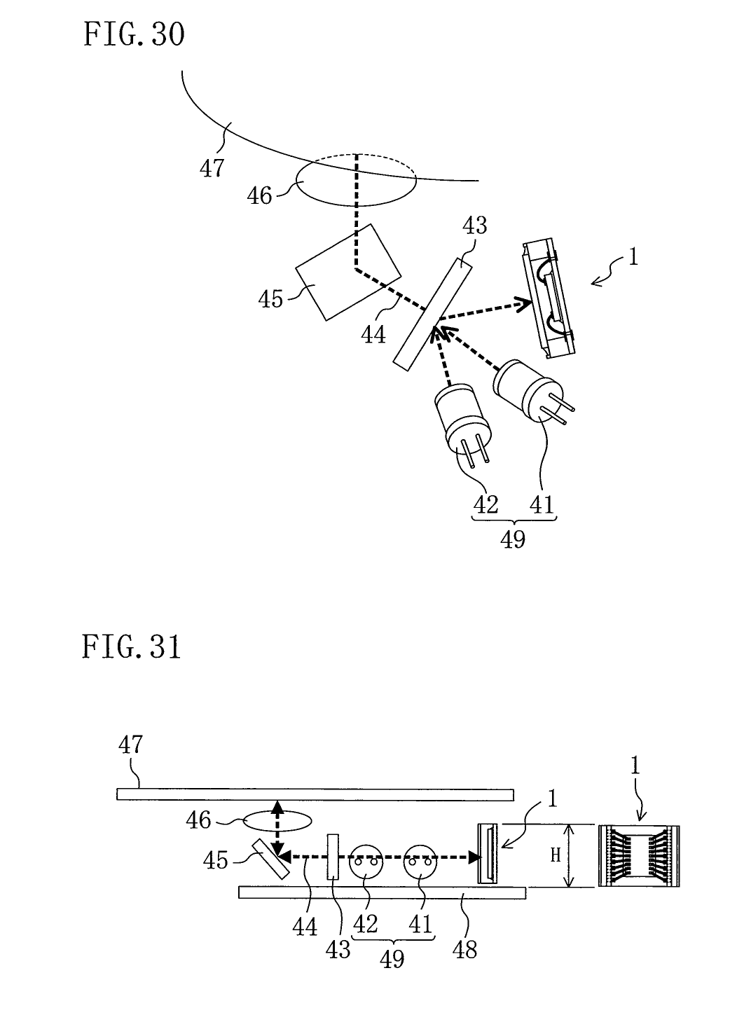

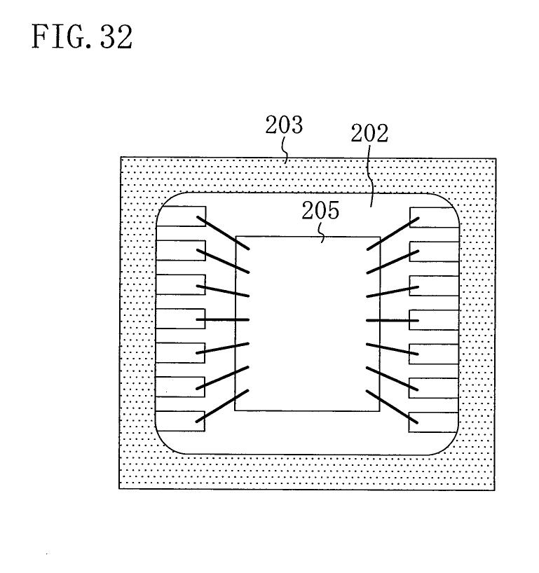

FIG. 30 is a perspective view schematically illustrating a configuration in which an optical pickup module according to this embodiment is placed under an optical disk 47. FIG. 31 is a side view of the configuration. The semiconductor device 1 at the right side of FIG. 31 is shown in order to depict the light-receiving surface of the semiconductor device 1 (photodetector) mounted on a support 48, which is located at the left of the right-side semiconductor device 1, with the semiconductor device 1 rotated 90° with respect to the vertical axis. The illustration does not mean that two semiconductor devices 1 are provided in the optical pickup module.

This optical pickup module includes the above-described semiconductor device 1 (photodetector), first and second laser devices 41 and 42, a beam splitter 43, a mirror 45, and an objective lens 46. The first and second laser devices constitute a laser module 49. Light 44 emitted from the first and second laser devices 41 and 42 passes through the beam splitter 43, is reflected on the mirror 45, and then strikes an information-recording surface of the optical disk 47 through the objective lens 46. The light 44 is then reflected on the information-recording surface, and enters the semiconductor device 1 by way of the objective lens 46, the mirror 45, and the beam splitter 43.

In this case, the first laser device 41 is a blue-violet laser device configured to emit laser light having a peak wavelength of 405 nm. The second laser device 42 is a dual-wavelength laser device configured to emit laser light with two wavelengths: red laser light having a peak wavelength of 650 nm; and infrared laser light having a peak wavelength of 780 nm.

Components constituting the optical pickup module are mounted on the support 48, and this support 48 is placed under the information-recording surface of the optical disk 47. Under the rotating optical disk 47, the optical pickup module moves along the radius of the optical disk 47. The surface of the support 48 on which the components are mounted is in parallel with the information-recording surface of the optical disk 47.

For convenience in establishing interconnection, the semiconductor device 1 is positioned in such a manner that the direction along which the first ribs 70, 70 extend is perpendicular to the support 48, i.e., to the information-recording surface of the optical disk 47. With this positioning, a plurality of external-connection portions 77, 77, . . . of the semiconductor device 1 are arranged in two lines perpendicularly to the mounting surface of the support 48. Accordingly, wires drawn from the external-connection portions 77, 77, . . . to establish connection to the outside are arranged within the height H of the semiconductor device 1 from the mounting surface of the support 48, resulting in reduction of the height of the entire optical pickup module.

As described above, the first ribs 70, 70 of the semiconductor device 1 extend perpendicularly to the support 48, and no ribs extend in parallel with the support 48. This configuration allows the height H of the semiconductor device 1 to be made approximately equal to the length of one side of the semiconductor element 10. As a result, the entire optical pickup module can be thinner, and smaller in size.

In the semiconductor device 1 of this embodiment, the lid 90 is bonded to the upper surfaces 70b of the first ribs 70, 70 provided on the pair of opposite external edges of the base 60 in the package 50, and no ribs are provided on another pair of opposite external edges, resulting in miniaturization of the entire semiconductor device. In addition, the adhesive 85 whose extension has been blocked by the dams 80, 80 adheres to the side surfaces of the lid 90 to form fillets, thus firmly fixing the lid 90 to the package 50.

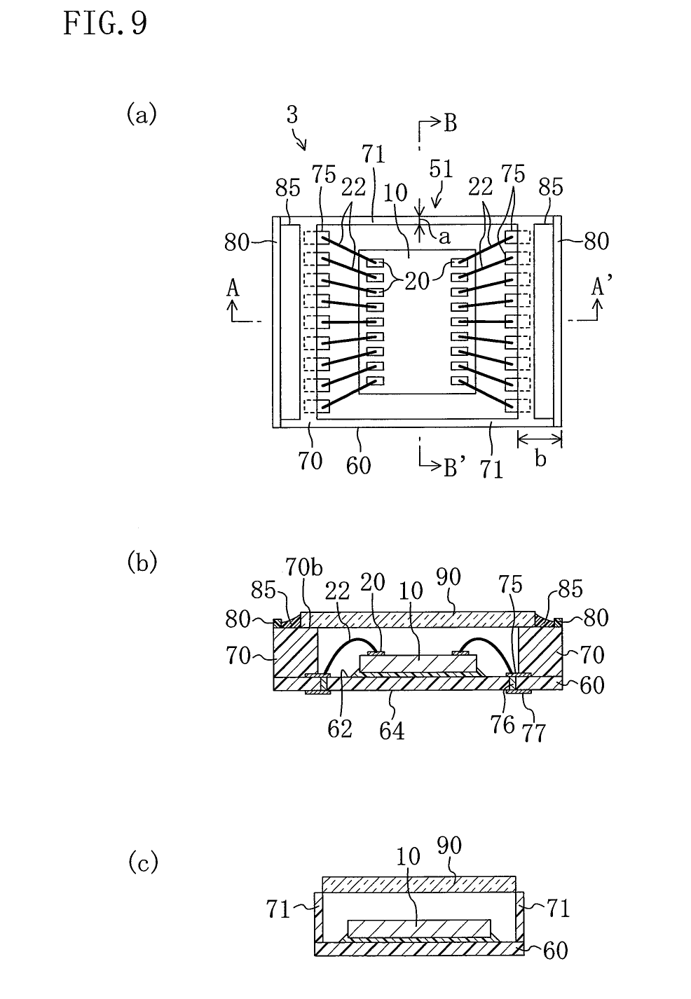

In this embodiment, the dams 80′ are cut in separating adjacent trenches 55, 55 in fabrication. Thus, neither stress nor load is applied to the adhesive 85, thus stabilizing the adhesive strength between the lid 90 and the first ribs 70, 70. On the other hand, in the semiconductor device illustrated in FIG. 9 of Patent Document 3, an adhesive itself is cut. Thus, stress might be applied to the adhesive to cause a variation in adhesive strength. In addition, in application of the adhesive, the adhesive might extend out from recesses. Moreover, if lids are placed one by one, the amount of an adhering adhesive might differ between both sides of a recess, whereas if the lids are placed at a time, the adhesive might be pushed from both sides to run on the lids. However, these problems do not arise in this embodiment.

### Embodiment 2

A semiconductor device according to a second embodiment differs from the semiconductor device 1 of the first embodiment only in that the dams 80 are removed from the semiconductor device 1 of the first embodiment. In the other aspects, the semiconductor device of the second embodiment is the same as that of the first embodiment, and thus only different aspects are now described.

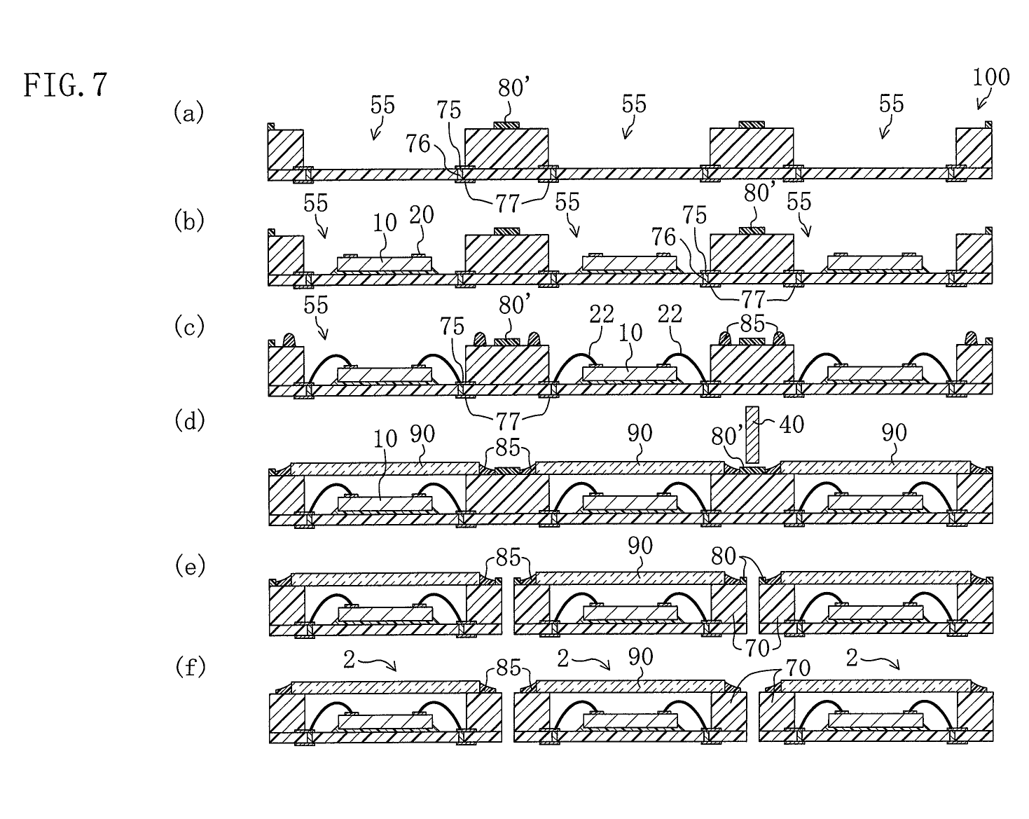

FIG. 7 shows process steps for fabricating a semiconductor device 2 of this embodiment in cross section. FIGS. 7(a) through 7(e) correspond to the process steps for fabricating the semiconductor device 1 of the first embodiment shown in FIG. 3. In this embodiment, adjacent trenches 55, 55 are separated by cutting with a dicing saw 40, and then dams 80, 80, . . . are removed as shown in FIG. 7(f). In this case, the dams 80, 80, . . . are made of a material to which an adhesive 85 does not adhere.

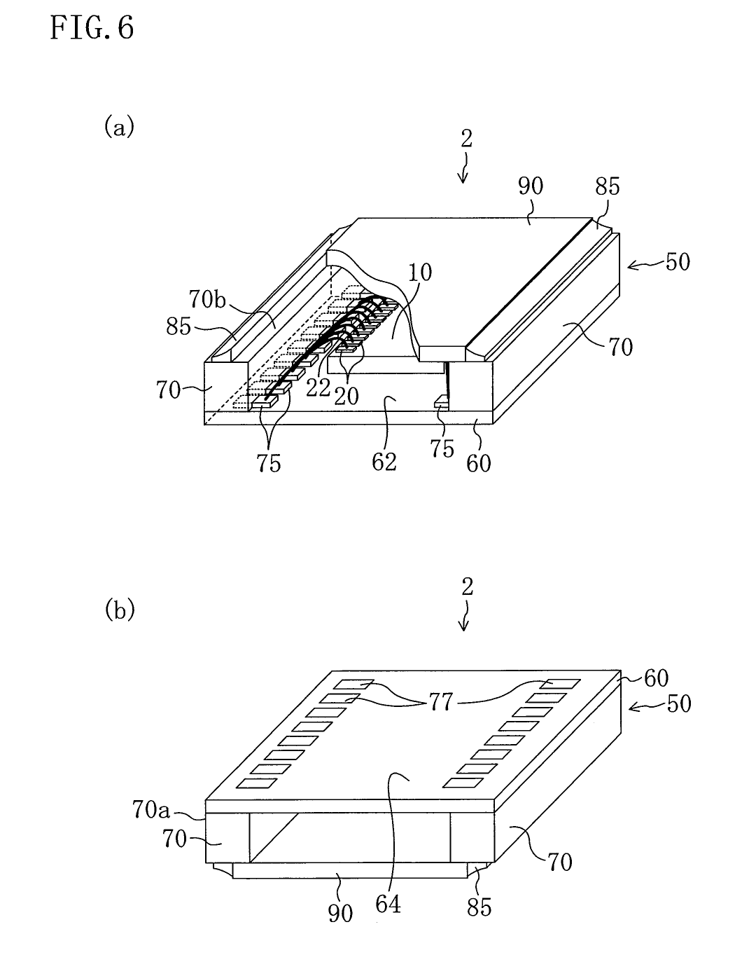

Accordingly, as shown in FIG. 6, the semiconductor device 2 of this embodiment employs the same package 50, semiconductor element 10, and lid 90 as those of the first embodiment. The lid 90 is bonded to first ribs 70, 70 with an adhesive 85 as in the semiconductor device 1 of the first embodiment, but no dams are provided unlike the first embodiment. The adhesive 85 of the semiconductor device 2 of this embodiment adheres to the side surfaces of the lid 90, and forms fillets toward first rib upper surfaces 70b. However, a trace of blockage by the dam 80 remains at an end of each of these fillets away from the side surface of the lid 90 (i.e., an end of each of the fillets opposite the end thereof facing the side surface). This trace is a cliff-like shape of the adhesive 85 that steeply falls toward the first rib upper surface 70b at a portion of a gentle slope of the adhesive 85 from the side surface of the lid 90 down to the first rib upper surface 70b.

In the semiconductor device 2 of this embodiment, the dams are removed in the manner described above, thus achieving smooth assembly without being caught in incorporating the semiconductor device 2 in an optical pickup module. In addition, similar advantages as those of the first embodiment are also obtained.

### Embodiment 3

A semiconductor device according to a third embodiment differs from the semiconductor device 1 of the first embodiment only in that second ribs are additionally provided. In the other aspects, the semiconductor device of the third embodiment is the same as that of the first embodiment, and thus only different aspects are now described.

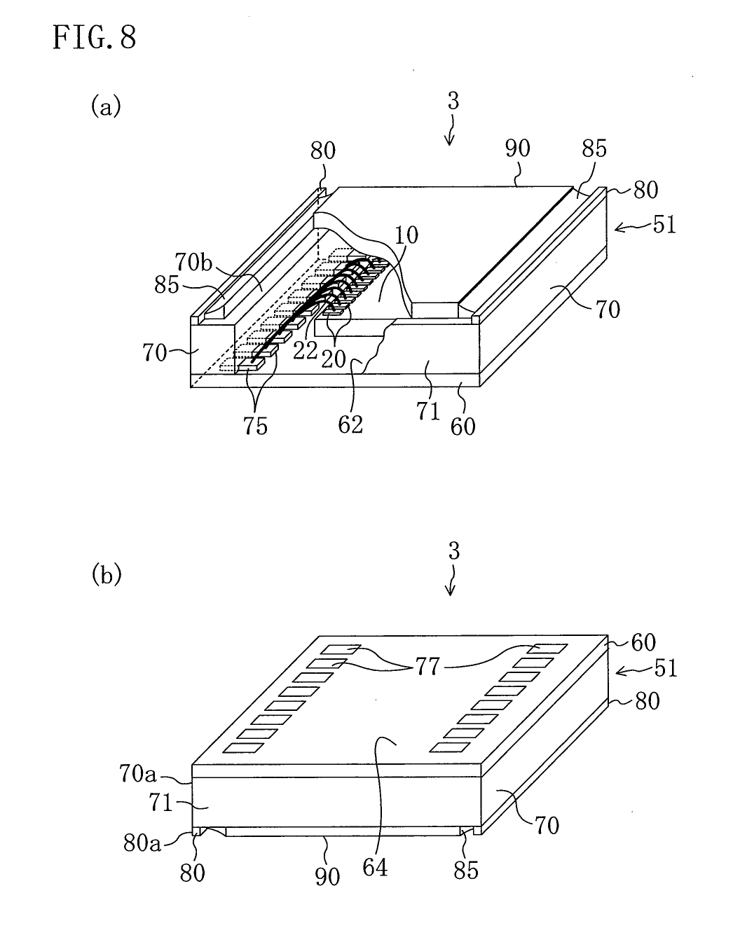

As illustrated in FIGS. 8 and 9, a semiconductor device 3 according to this embodiment includes first ribs 70, 70 and second ribs 71, 71. The side surfaces of the semiconductor device which are open to the outside in the semiconductor device 1 of the first embodiment is closed in this embodiment by the second ribs 71, 71 such that the semiconductor element 10 is sealed. The second ribs 71, 71 extend perpendicularly to the direction along which the first ribs 70, 70 extend. For convenience of description, a lid 90 is removed and is not shown in FIG. 9(a).

The second ribs 71, 71 are provided on a pair of opposite external edges of a mounting surface 62 of a base 60 and project upward from the base 60. The pair of opposite external edges on which the second ribs 71, 71 are provided is different from a pair of opposite external edges of the mounting surface on which the first ribs 70, 70 are provided. These pairs of opposite external edges are perpendicular to each other.

In this embodiment, the edges of the upper surfaces of the second ribs 71, 71 facing the inside of a package 51 are in contact with external edges of the lid 90, and capillary action causes an adhesive 85 to enter the portions at which the second ribs 71, 71 are in contact with the lid 90 near the first ribs 70, 70, thereby bonding the second ribs 71, 71 and the lid 90 together with the adhesive 85. The contact between the second ribs 71, 71 and the lid 90 allows the semiconductor element 10 to be sealed in. Accordingly, it is possible to prevent dust from entering the package 51, thus preventing short-circuit of wires and, in a case where a semiconductor element 10 is an optical element, also preventing functional failures caused by dust accumulated on the optical functional surface.

The width a (i.e., the width perpendicular to the direction along which the second ribs 71 extend) of each of the second ribs 71 is smaller than the width b (i.e., the width perpendicular to the direction along which the first ribs 70 extend) of each of the first ribs 70. This is because the first ribs 70 have the function of fixing the lid 90, and the second ribs 71 do not have such a function and only need to prevent entering of dust.

In this embodiment, the length of the semiconductor device 3 along which the first ribs 70, 70 extend is larger than that of the semiconductor device 1 of the first embodiment by a distance corresponding to the width a×2 of the second ribs 71, 71. However, since the width a is smaller than the width b of each of the first ribs 70, 70, the increase in the length is suppressed to a small value. The width a is preferably less than or equal to 1/2 of the width b, and more preferably less than or equal to ¼ of the width b. It is sufficient that the width a is greater than or equal to 10 μm. In this manner, the second ribs 71, 71 can prevent dust from entering the package 51. In addition, the length of the semiconductor device 3 in the longitudinal direction of the first ribs 70, 70 can be smaller than that in conventional devices, resulting in miniaturization of the entire semiconductor device 3. In addition to these advantages, the semiconductor device 3 of this embodiment has advantages similar to those obtained in the first embodiment.

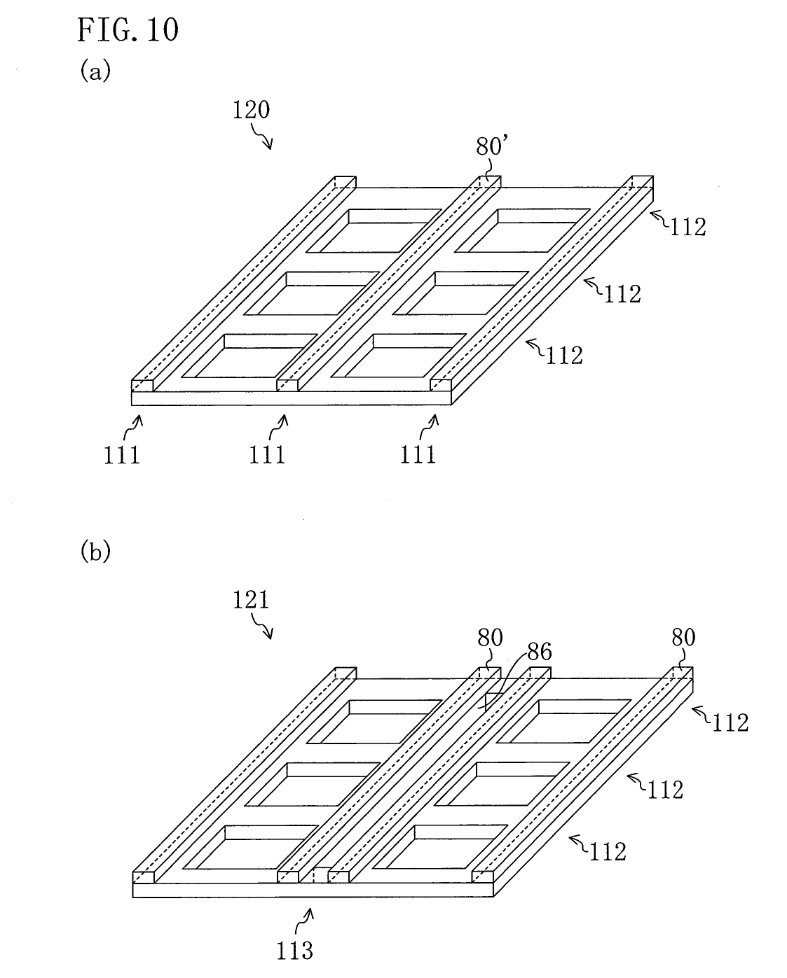

Fabrication of the semiconductor device 3 of this embodiment employs a package board assembly obtained by attaching a lattice member 120 illustrated in FIG. 10(a) to a flat board. FIG. 10(a) illustrates only part of the entire lattice member 120, and the other part is omitted. Out of components of the lattice member 120, components on which dams 80′ are provided are first members 111. Part of the first members 111 serves as the first ribs 70. Components of the lattice member 120 perpendicular to the first members 111 are second members 112. Part of the second members 112 serves as the second ribs 71.

This lattice member 120 is attached to a board, thereby forming a package-assembled board. In this package-assembled board, the board forms the bottoms of holes in the lattice, thereby forming recesses. These recesses are arranged in rows and columns, i.e., a plurality of recesses form a matrix. Semiconductor elements 10 are respectively placed on the recesses, and are wire bonded. Each of the first members 111 is located between adjacent rows of the recesses. The dams 80′ are respectively provided in middle portions of the upper surfaces of the first members 111, and extend along the rows of the recesses. Each of the second members 112 is located between adjacent columns of the recesses.

As in the first embodiment, an adhesive 85 is continuously applied along the dams 80′. Then, lids 90 are placed over the respective recesses, and are bonded to the package-assembled board. At this time, external edge portions of the lids 90 are placed on the adhesive 85.

The adhesive 85 is then hardened by heat or ultraviolet radiation. Then, middle portions of the dams 80′ are cut with a dicing saw, thereby dividing each of the first members 111 into two. Middle portions of the second members 112 are also cut with a dicing saw, thereby dividing each of the second members 112 into two. In this manner, individual semiconductor devices 3 are obtained.

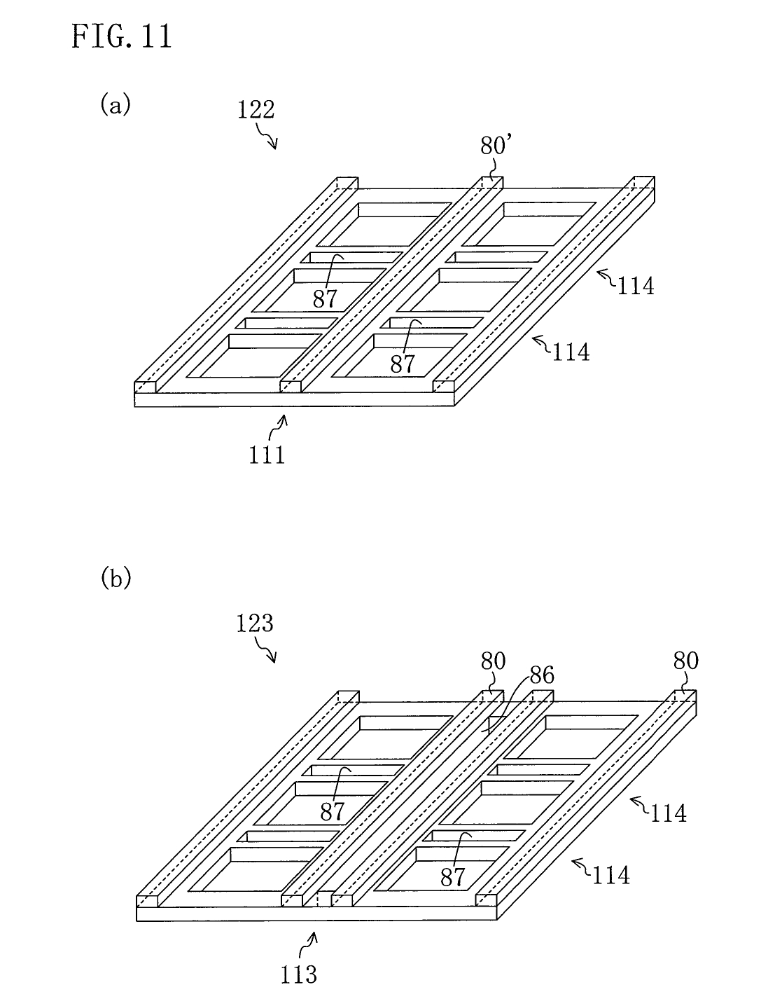

The package board assembly may be formed by using a lattice member 121, 122, or 123 illustrated in FIG. 10(b), FIG. 11(a), or FIG. 11(b). As in the package board assembly illustrated in FIG. 5, in the lattice member 121 illustrated in FIG. 10(b), slits 86 are provided in middle portions of first members 113, thus facilitating division of the first members 113. In the lattice member 122 illustrated in FIG. 11(a), slits 87 are provided in second members 114, thus facilitating division of the second members 114. In the lattice member 123 illustrated in FIG. 11(b), slits 86 and 87 are provided on both of the first members 113 and the second members 114, thus facilitating division of each of the first members 113 and the second members 114.

In each of the lattice members 120, 121, 122, and 123, the width of the second members 112, 114 between adjacent columns of the recesses is smaller than or equal to the width of the first members 111, 113 between adjacent rows of the recesses such that the width b of the first ribs 70 is larger than the width a of the second ribs 71 in the semiconductor device 3 as a final product.

In this embodiment, the second ribs 71, 71 are in contact with the lid 90 such that the semiconductor element 10 is sealed in. Alternatively, the second ribs 71, 71 may not be in contact with the lid 90 as long as the distance between the second ribs 71, 71 and the lid 90 is within about several tens of micrometers because it is possible, in this case, to prevent entering of dust and other substances which might cause functional failures or short-circuit in the semiconductor element 10.

### Embodiment 4

A semiconductor device according to a fourth embodiment differs from the semiconductor device 3 of the third embodiment only in that the dams 80 are removed. In the other aspects, the semiconductor device of the fourth embodiment is the same as that of the third embodiment, and thus only different aspects are now described.

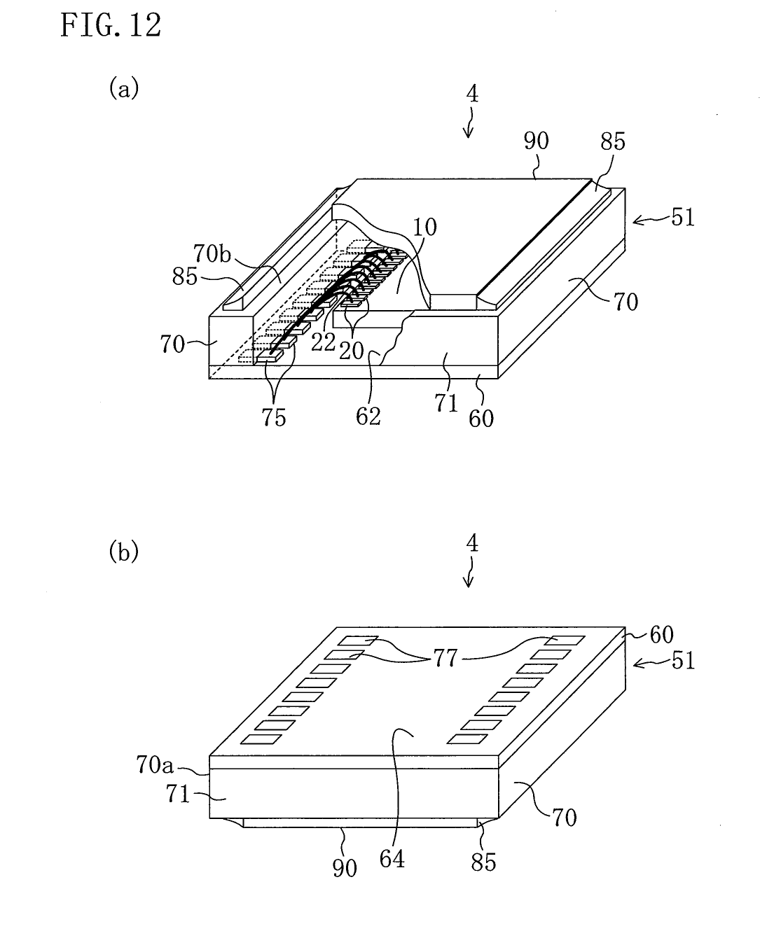

As illustrated in FIG. 12, a semiconductor device 4 according to this embodiment is fabricated by removing the dams 80 after, or in the middle of, fabrication of the semiconductor device 3 of the third embodiment. Accordingly, the semiconductor device 4 of this embodiment has a structure, a configuration, and a shape obtained by removing the dams 80 from the semiconductor device 3 of the third embodiment. Specifically, as in the semiconductor device 2 of the second embodiment, an adhesive 85 adheres to the side surfaces of a lid 90, and forms fillets toward first rib upper surfaces 70b. A trace of blockage by the dams 80 remains at an end of each of these fillet away from the side surface of the lid 90 (i.e., an end of each of the fillets opposite the end thereof facing the side surface).

In addition to the advantages of the third embodiment, the semiconductor device 4 of this embodiment has an advantage of smooth assembly without being caught in incorporating the semiconductor device 4 in an optical pickup module.

### Embodiment 5

A semiconductor device according to a fifth embodiment differs from the semiconductor device 3 of the third embodiment in the relationship between the second ribs 71, 71 and the lid 90. In the other aspects, the semiconductor device of the fifth embodiment is the same as that of the third embodiment, and thus only different aspects are now described.

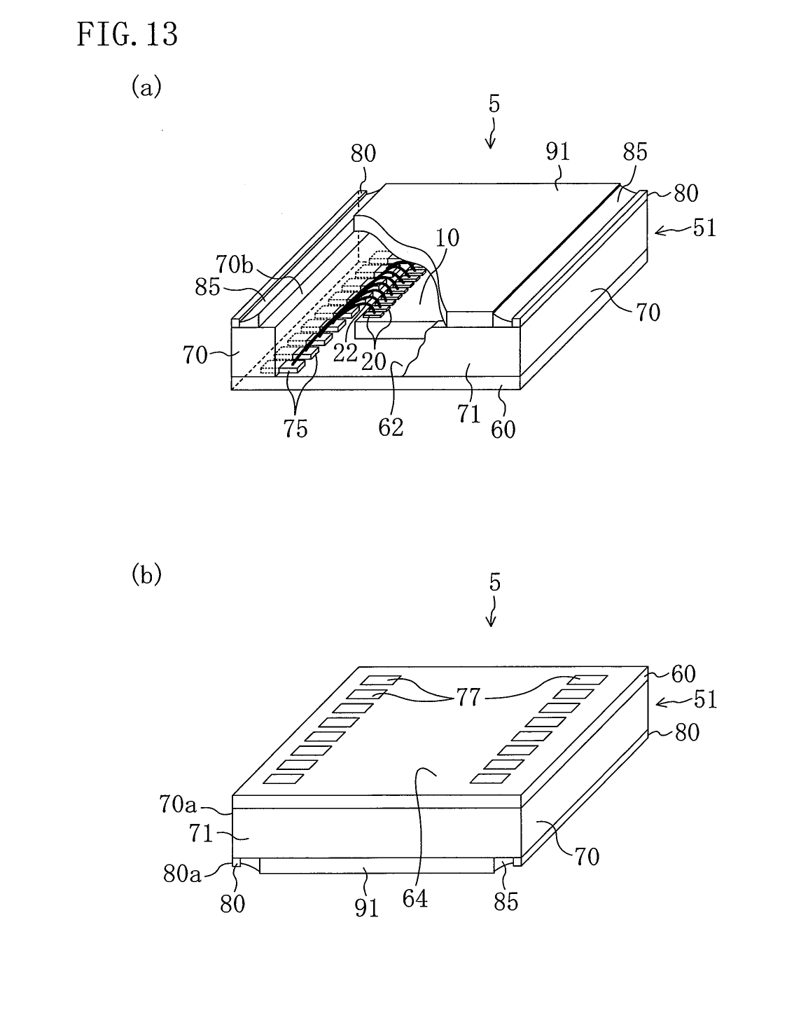

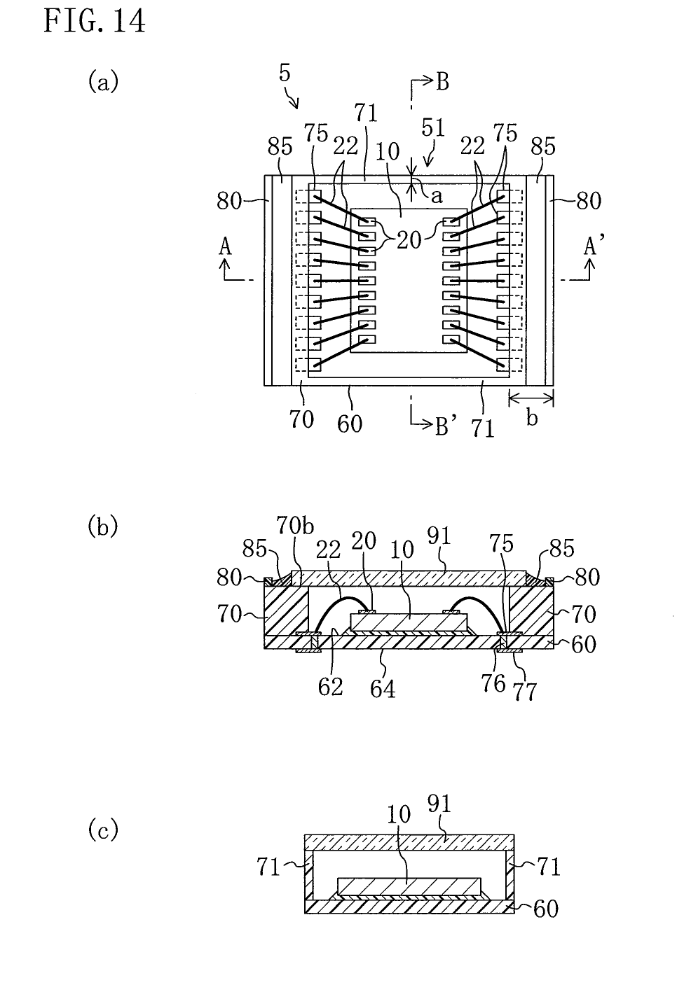

As illustrated in FIGS. 13 and 14, in a semiconductor device 5 according to this embodiment, edge portions of a lid 91 overlap the upper surfaces of second ribs 71, 71, and the lid 91 and the second ribs 71, 71 are bonded together with an adhesive 85 in these overlapping portions. Specifically, the lid 91 of this embodiment is longer than the lid 90 of the third embodiment along the direction in which first ribs 70, 70 extend. The lid 91 covers the upper surfaces of the second ribs 71, 71 such that the side surfaces of the lid 91 are flush with the external side wall surfaces of the second ribs 71, 71. For convenience of description, the lid 91 is removed and is not shown in FIG. 14(a). In the same manner, for convenience of description, portions of the adhesive 85 between the lid 91 and the first ribs 70, 70 and between the lid 91 and the second ribs 71, 71 are not shown in FIGS. 14(b) and 14(c).

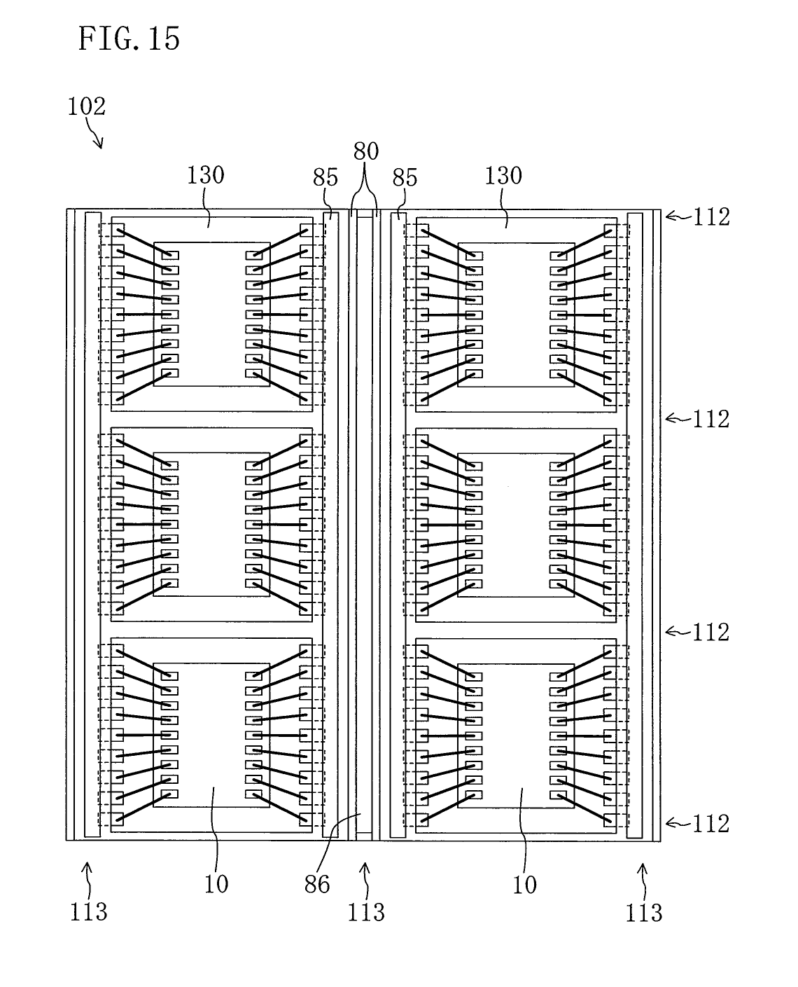

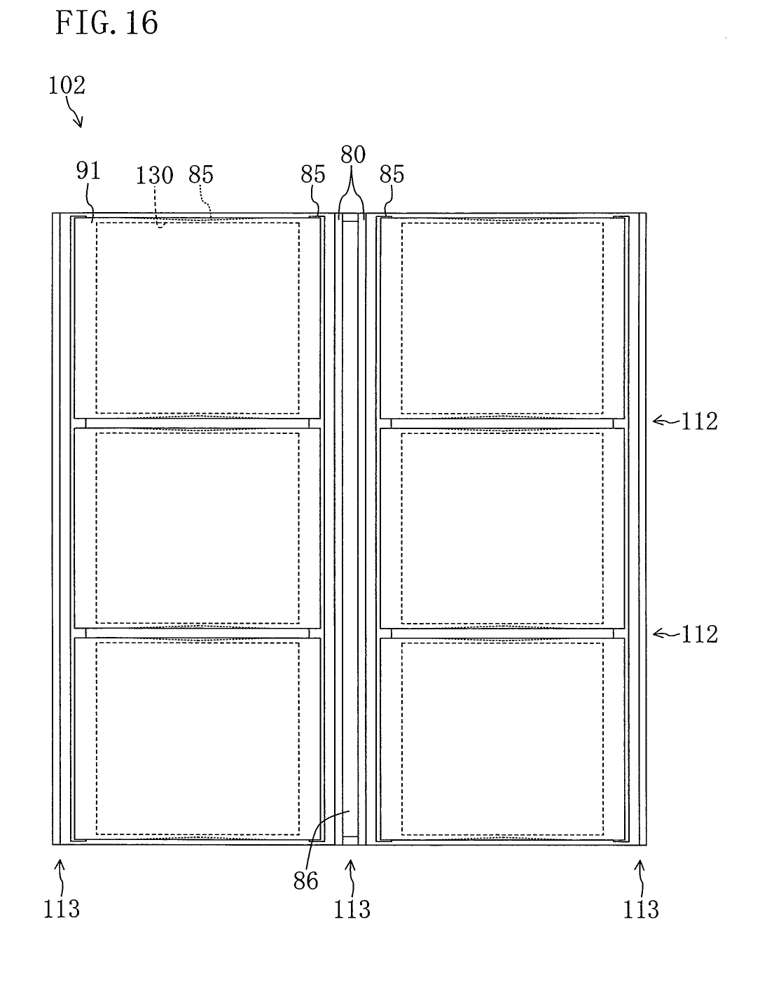

Now, adhesion between the lid 91 and a package 51 is described with reference to FIGS. 15 and 16.

FIG. 15 shows a configuration in which semiconductor elements 10 are mounted on, and bonded to, recesses in a package-assembled board 102 and in which an adhesive 85 is continuously applied, along dams 80, onto the upper surfaces of first members 113 serving as first ribs. The package-assembled board 102 further extends in the vertical and horizontal direction in the drawing, but only part of the package-assembled board 102 is shown in the drawings. This package-assembled board 102 is fabricated by using the lattice member 121 illustrated in FIG. 10(b). The adhesive 85 continuously extends to portions between columns of recesses 130 (i.e., portions on which second members are provided).

Thereafter, as illustrated in FIG. 16, lids 91 are placed to cover the respective recesses 130. In this placement, one lid 91 is associated with one recess 130, and spacing is provided between adjacent lids 91 disposed in the column direction. External edge portions of the lids 91 located above the upper surfaces of the first members 113 are directly placed on the adhesive 85 on the first members 113, and thus the adhesive 85 adheres to these external edge portions of the lids 91. On the other hand, under external edge portions of the lids 91 located above the upper surfaces of the second members 112, the adhesive 85 enters portions between the lids 91 and the second members 112 by capillary action. Accordingly, the second members 112 and the lids 91 are bonded together with the adhesive 85 without application of the adhesive 85 onto the second members 112, thus more firmly fixing the lids 91 to the package 51 than in the third embodiment. In addition, the lids 91 completely cover the openings of the recesses 130, thus ensuring prevention of entering of dust. Moreover, the same advantages as those of the third embodiment are also obtained.

Fabrication of the package-assembled board of this embodiment may employ one of the lattice members 120, 122, and 123 illustrated in FIGS. 10(a), 11(a), and 11(b). In the case of the lattice members 120 and 122, wide dams 80′ are placed on the first members 111 with no slits. To separate the rows in the lattice, the first members 113 including the dams 80′ thereon are cut.

### Embodiment 6

A semiconductor device according to a sixth embodiment differs from the semiconductor device 5 of the fifth embodiment only in that the dams 80 are removed from the semiconductor device 5. In the other aspects, the semiconductor device of the sixth embodiment is the same as that of the fifth embodiment, and thus only different aspects are now described.

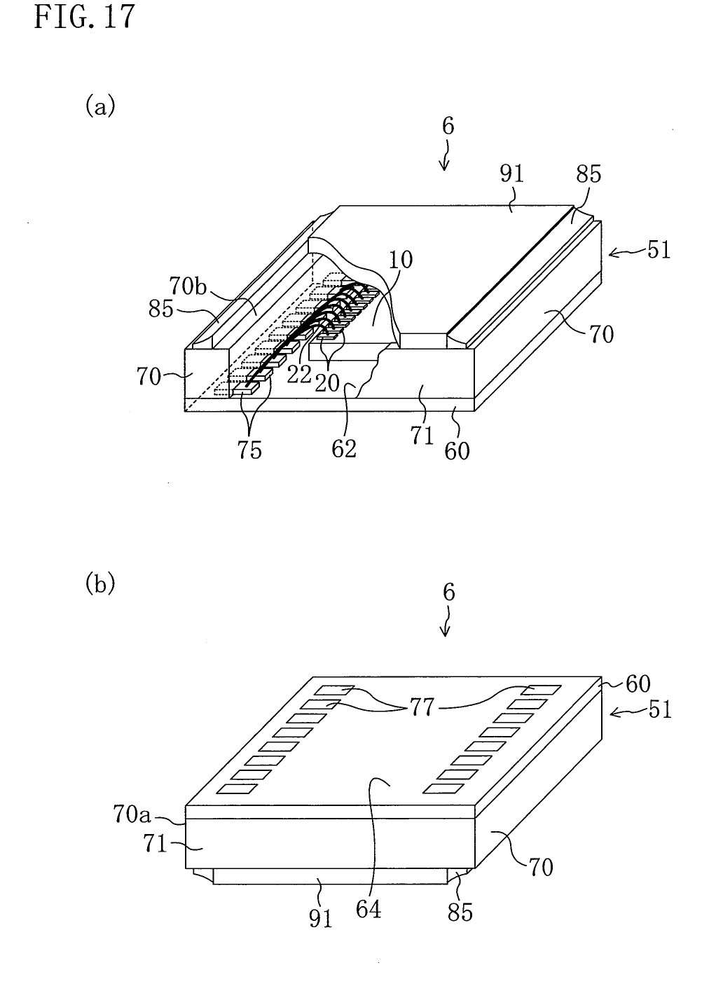

A semiconductor device 6 according to this embodiment illustrated in FIG. 17 is fabricated by removing dams 80 after, or in the middle of, fabrication of the semiconductor device 5 of the fifth embodiment. Accordingly, the semiconductor device 6 of this embodiment has a structure, a configuration, and a shape obtained by removing the dams 80 from the semiconductor device 5 of the fifth embodiment. Specifically, as in the semiconductor device 2 of the second embodiment, an adhesive 85 adheres to the side surfaces of a lid 91, and forms fillets toward first rib upper surfaces 70b. A trace of blockage by the dams 80 remains at an end of each of these fillet away from the side surface of the lid 91 (i.e., an end of each of the fillets opposite the end thereof facing the side surface).

In addition to the advantages of the fifth embodiment, the semiconductor device 6 of this embodiment has an advantage of smooth assembly without being caught in incorporating the semiconductor device 6 in an optical pickup module.

### Embodiment 7

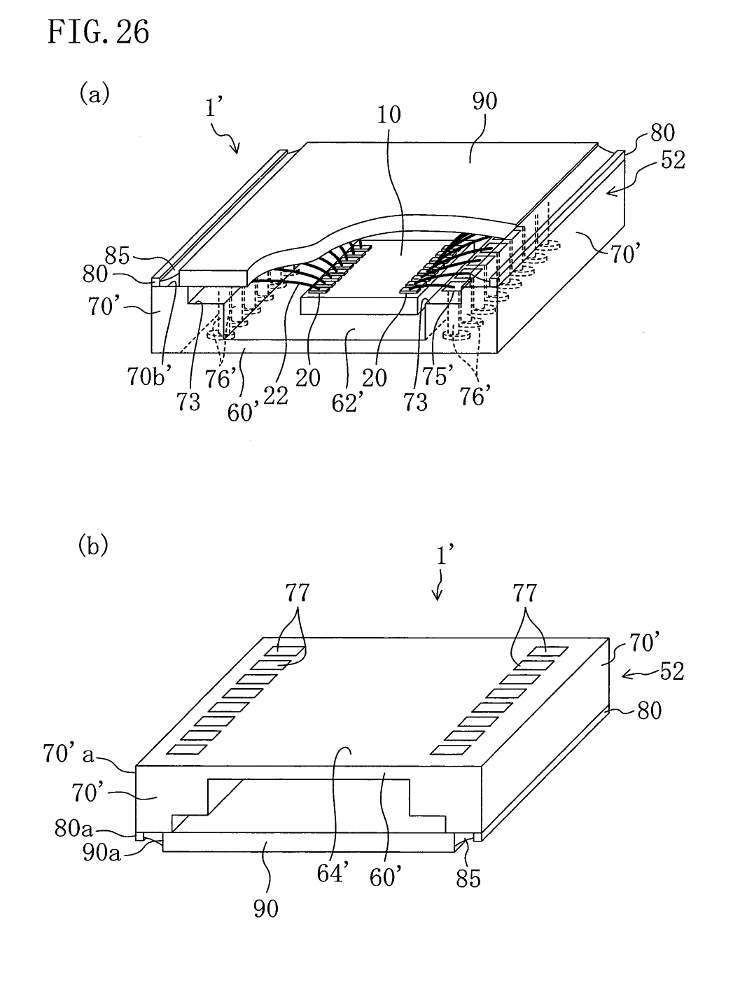

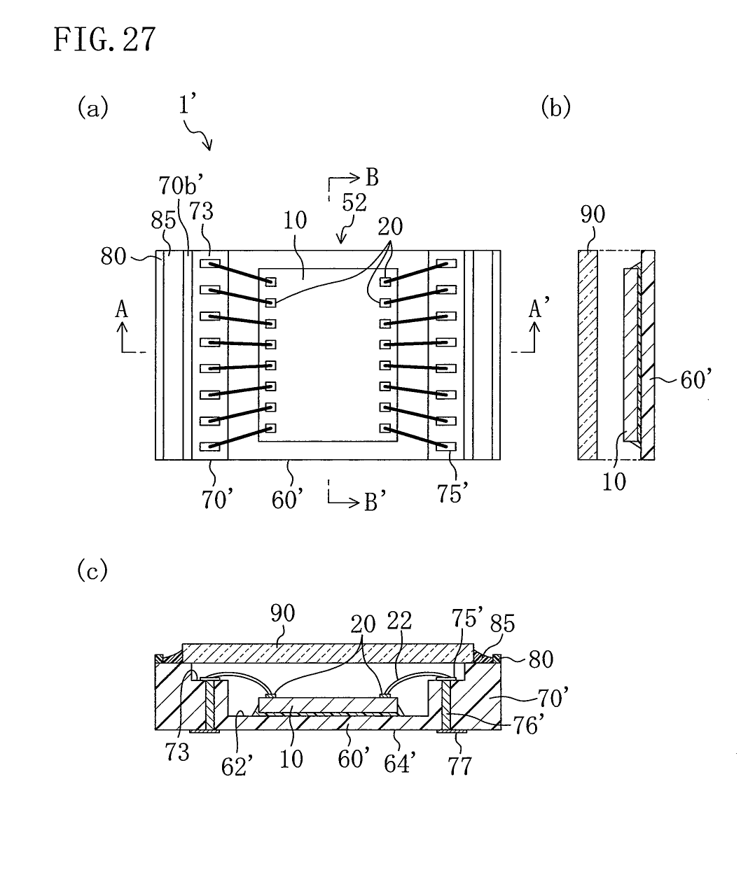

A semiconductor device according to a seventh embodiment differs from the semiconductor device 1 of the first embodiment only in a package. Now, a semiconductor device 1′ according to this embodiment, particularly aspects different from those of the semiconductor device 1 of the first embodiment, is described with reference to FIGS. 26 and 27.

A package 52 of this embodiment includes: a rectangular base 60′; two first ribs 70′, 70′ respectively extending along a pair of opposite sides of the rectangle; and dams 80, 80 respectively provided on first rib upper surfaces 70b′. Rib stepped portions 73 are also provided in such a manner that the rib stepped portions 73 are located below the first rib upper surfaces 70b′ at a distance corresponding to a step toward a semiconductor element 10. Connecting electrode 75′, 75′, . . . are formed on the rib stepped portions 73. The first ribs 70′, 70′ project upward from a pair of opposite external edges of a rectangular mounting surface 62′ of a base 60′ on which the semiconductor element 10 is mounted. Each of the first ribs 70′, 70′ are in the shape of a rectangular solid extending along an associated one of the external edges of the mounting surface 62′.

A plurality of internal interconnections (buried interconnections) 76′, 76′, . . . are provided in the first ribs 70′, 70′. The internal interconnections 76′ are connected to the connection electrodes 75′ on the rib stepped portions 73, and are connected to external-connection portions 77 on the surface (i.e., a non-mounting surface 64′) at the opposite side. The connection electrodes 75 on the rib stepped portions 73 are connected to electrode pads 20, 20 of the semiconductor element 10 by metal wires 22. The dams 80, 80 are located closer to the outside than the connection electrodes 75 on the first rib upper surfaces 70b, and extend in parallel with the ribs 70′, 70′.

As in the first embodiment, a lid 90 is bonded to a package 52 with an adhesive 85 with external edge portions of the lid 90 located on the first rib upper surfaces 70b′.

The distance between the first rib upper surfaces 70b′ and the rib stepped portions 73 is greater than the diameter of the metal wires 22, and bonding of the metal wires 22 to the connection electrodes 75′ is the second bonding. Thus, it is possible to prevent the lid 90 placed on the first rib upper surfaces 70b′ of the base from being in contact with the metal wires 22 and pushing the metal wires 22, resulting in high connection reliability of the metal wires 22. In addition, since the distance between the first rib upper surfaces 70b′ and the rib stepped portions 73 is less than or equal to twice as large as the diameter of the metal wires 22, the thickness of the semiconductor device 1′ can be reduced, resulting in miniaturization of the semiconductor device 1′.

In the semiconductor device 1′ of this embodiment, adhesion between the lid 90 and the package 52 is obtained in the same manner as in the first embodiment, and the package length along the direction in which the first ribs 70′, 70′ extend is also the same as in the first embodiment. Thus, similar advantages to those in the first embodiment are obtained. In addition, since the connection electrodes 75′ are provided on the rib stepped portions 73, the area on which the semiconductor element 10 is mounted is minimized, which contributes to miniaturization of the semiconductor device 1′.

The semiconductor device 1′ of this embodiment can be fabricated by a method similar to that for the semiconductor device 1 of the first embodiment. In the semiconductor device 1′ of this embodiment, the dams 80, 80 may be removed after fabrication of the device.

### Embodiment 8

A semiconductor device according to an eighth embodiment is obtained by adding second ribs to the semiconductor device 1′ of the seventh embodiment, and the other aspects of the eighth embodiment are the same as those in the seventh embodiment. Thus, only different aspects are now described.

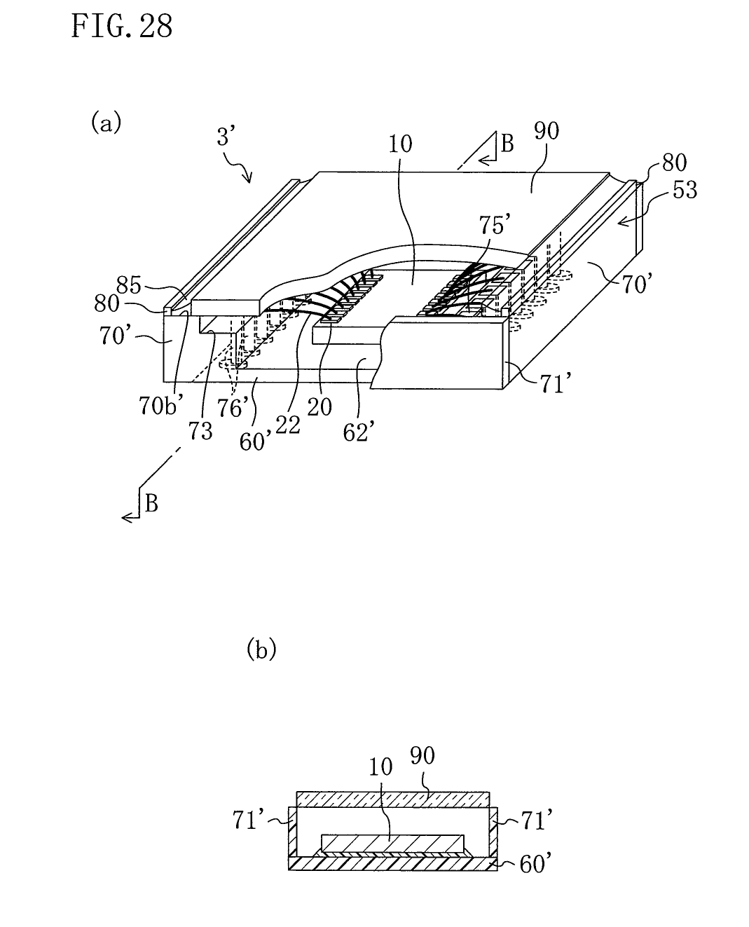

FIG. 28 illustrates a semiconductor device 3′ according to this embodiment. In the semiconductor device 3′ of this embodiment, second ribs 71′, 71′ are respectively provided on a pair of opposite external edges of a base 60′ different from a pair of opposite external edges of the base 60′ on which first ribs 70′, 70′ are provided. Each of the second ribs 71′, 71′ extends from an end, in the longitudinal direction, of one of the first ribs 70′, 70′ to an end of the other first rib 70′. That is, a package 53 of this embodiment is obtained by adding the second ribs 71′, 71′ to the package 52 of the seventh embodiment.

The second ribs 71′, 71′, together with rib external side wall surfaces 70a, constitute the side wall surfaces at the four sides of the package 53. The height of the second ribs 71′, 71′ from a base mounting surface 62′ is equal to the height of the first ribs 70′. The width (i.e., the width perpendicular to the longitudinal direction) of each of the upper surfaces of the second ribs 71′ is smaller than the width (i.e., the width perpendicular to the longitudinal direction) of each of the upper surfaces of the first ribs 70′. The second ribs 71′, 71′ can prevent dirt and dust from entering the semiconductor device 3′ from the outside, thus preventing the dirt and dust from accumulating on the light-receiving surface of a semiconductor element 10. The length of the semiconductor device 3′ along which the first ribs 70′, 70′ extend is larger than that of the semiconductor device 1′ of the seventh embodiment by a distance corresponding to the widths of the respective second ribs 71′, 71′. However, since the width of each of the second ribs 71′ is smaller than the width of each of the first ribs 70′, the increase in the length is suppressed to a small value. The width of each of the second ribs 71′ is preferably less than or equal to ½ of the width of each of the first ribs 70′, and more preferably less than or equal to ¼ of the width of each of the first ribs 70′. It is sufficient that the width of each of the second ribs 71′ is greater than or equal to 10 μm.

In this embodiment, edges of the upper surfaces of the second ribs 71′, 71′ facing the inside of the package 53 are in contact with external edges of a lid 90, and capillary action causes an adhesive 85 to enter portions at which the second ribs 71′, 71′ are in contact with the lid 90 near the first ribs 70′, 70′, thereby bonding the second ribs 71′, 71′ and the lid 90 together with the adhesive 85.

The semiconductor device 3′ of this embodiment can be fabricated by a method similar to that for the semiconductor device of the seventh embodiment. That is, after fabrication of the semiconductor device of the seventh embodiment, the second ribs 71′, 71′ are attached to the semiconductor device of the seventh embodiment, thereby completing fabrication of the semiconductor device 3′ of this embodiment. In the semiconductor device 3′ of this embodiment, dams 80, 80 may be removed after fabrication of the semiconductor device 3′.

### Embodiment 9

A semiconductor device according to a ninth embodiment differs from the semiconductor device 3′ of the eighth embodiment only in the relationship between the second ribs 71′, 71′ and the lid 90. In the other aspects, the semiconductor device of the ninth embodiment is the same as that of the eighth embodiment, and thus only different aspects are now described.

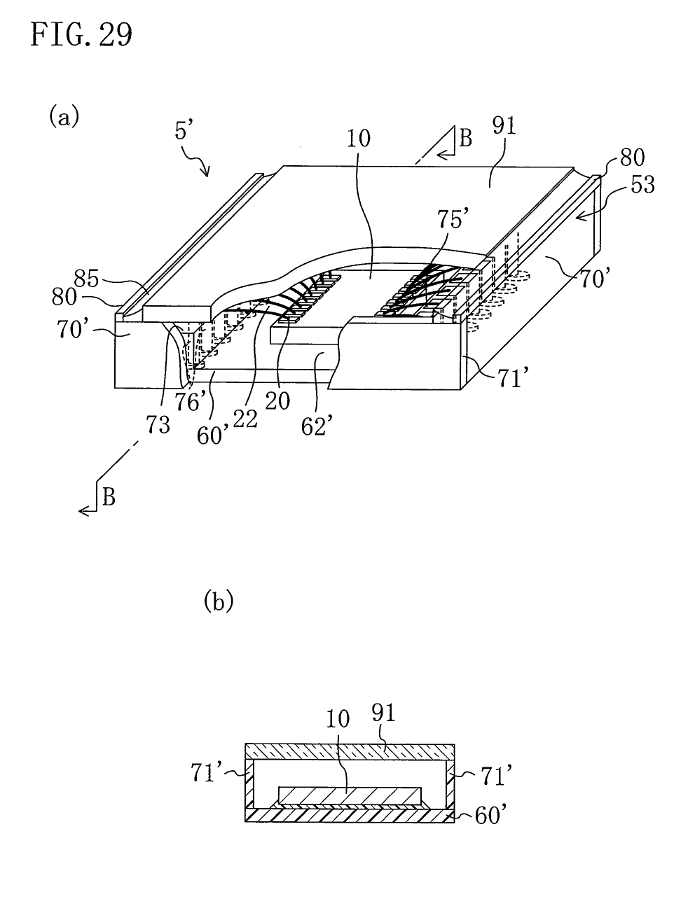

As illustrated in FIG. 29, in a semiconductor device 5′ according to this embodiment, edge portions of a lid 91 overlap the upper surfaces of second ribs 71′, 71′, and the lid 91 and the second ribs 71′, 71′ are bonded together with an adhesive 85 in these overlapping portions. Specifically, the lid 91 of this embodiment is longer than the lid 90 of the eighth embodiment along the direction in which first ribs 70′, 70′ extend. The lid 91 covers the upper surfaces of the second ribs 71′, 71′ such that side surfaces of the lid 91 are respectively flush with the external side wall surfaces of the second ribs 71′, 71′. The bonding between the edge portions of the lid 91 and the upper surfaces of the second ribs 71′, 71′ are the same as that in the fifth embodiment, and thus description thereof is omitted.

In this embodiment, the lid 91 is more firmly bonded to a package 53 than in the eighth embodiment. In addition, the opening of the package 53 is completely covered with the lid 91, thus ensuring prevention of entering of dust. Moreover, the same advantages as those in the eighth embodiment are obtained. In the semiconductor device 5′ of this embodiment, dams 80, 80 may also be removed after fabrication of the semiconductor device 5′.

### Reference Embodiment 1

### —Semiconductor Device—

A semiconductor device according to a first reference embodiment differs from the semiconductor device of the first embodiment in that a plate-like transparent member replaces the transparent flat lid and is placed on a semiconductor element, and that a trench in the package is filled with an encapsulating resin in such a manner that side surfaces of the transparent member and metal wires are buried in the resin. Now, the first reference embodiment, particularly aspects thereof different from those of the first embodiment, is described. The same aspects as those of the first embodiment may be omitted in the following description.

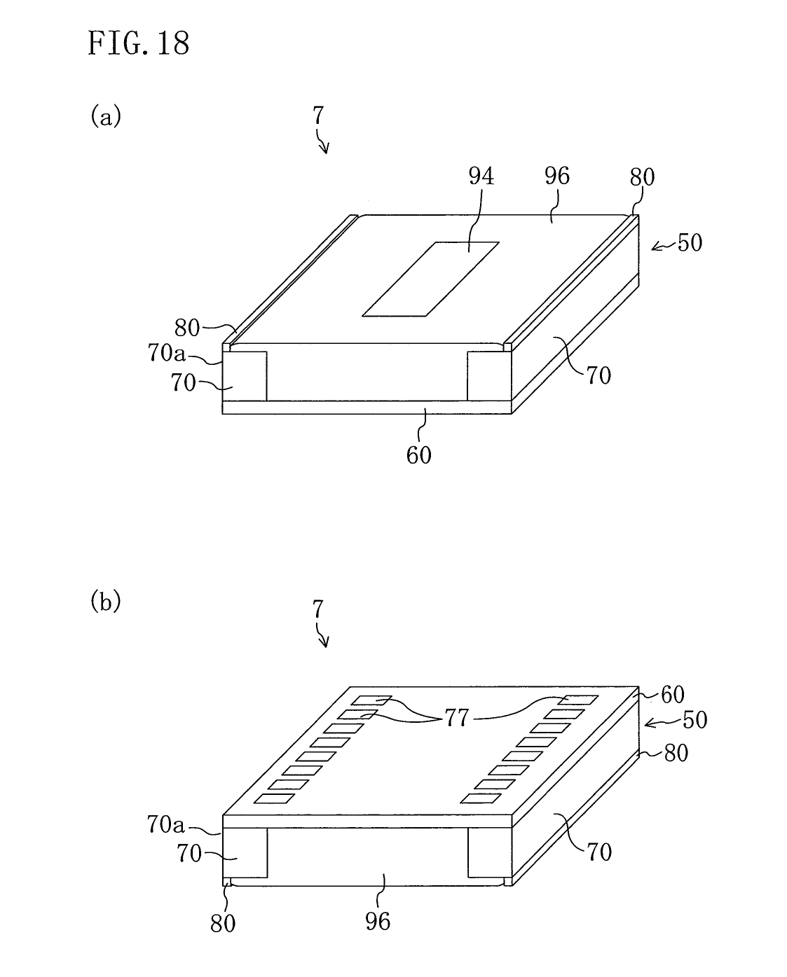

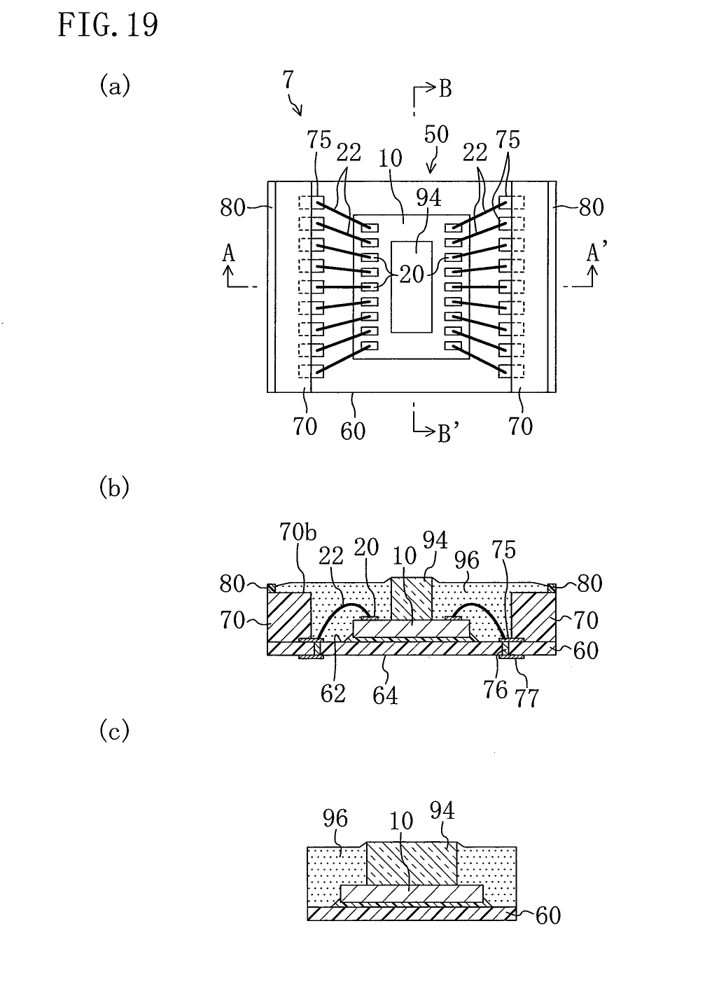

FIGS. 18(a) and 18(b) and FIGS. 19(a) through 19(c) illustrate a semiconductor device 7 according to this reference embodiment. In FIG. 19(a), an encapsulating resin 96 is not shown for convenience of description. In this reference embodiment, a package 50, a semiconductor element 10, dams 80, 80, first ribs 70, 70, and metal wires 22 are the same as those in the first embodiment, and a configuration for connecting connection electrodes 75 to external-connection portions 77 and a configuration for connecting a semiconductor element 10 to the connection electrodes 75 are also the same as those in the first embodiment.

The semiconductor element 10 mounted on the package 50 is connected to the connection electrodes 75 by the metal wires 22. A plate-like transparent member 94 is placed to cover the light-receiving surface of the semiconductor element 10 with a transparent adhesive interposed between the semiconductor element 10 and the transparent member 94. The transparent member 94 is a plate-like member having a rectangular upper surface and made of glass, and adheres to the semiconductor element 10.

In addition, components provided in a trench (a recess) of the package 50 except for the upper surface of the transparent member 94 and the upper surfaces of the dams 80, 80 are encapsulated with the encapsulating resin 96. Specifically, side surfaces of the transparent member 94, the upper surfaces of the first ribs 70, 70, and the metal wires 22, for example, are buried in the encapsulating resin 96. When viewed from above the semiconductor device 7 of this reference embodiment, only the upper surface of the transparent member 94 and the upper surfaces of the dams 80, 80 are exposed, and the other components are covered with the encapsulating resin 96. Accordingly, no dirt and dust accumulate on the light-receiving surface of the semiconductor element 10, electrode pads 20, the connection electrodes 75, and the metal wires 22, thus avoiding failures such as short circuits caused by dirt and dust. The encapsulating resin is preferably one of a thermosetting epoxy resin, a filler-added resin containing, for example, SiO₂, and a resin which contains a dye and exhibits a light-blocking property, for example.

The encapsulating resin 96 is a high-viscosity liquid when filling the trench of the package 50, and is then cured. At the side wall surfaces of the semiconductor device 7 except for first rib external side wall surfaces 70a, the encapsulating resin 96 is flush with the end surfaces of the first ribs 70, 70. The metal wires 22 are completely buried in the encapsulating resin 96, and thus portions of the metal wires 22 in contact with the electrode pads 20 and with the connection electrodes 75 are fixed, thus enhancing connection reliability. In addition, since the upper surface of the transparent member 94 is exposed and the side surfaces of the transparent member 94 are buried in the encapsulating resin 96, only light that has passed through the upper surface of the transparent member 94 reaches the light-receiving surface of the semiconductor element 10. Even when light enters the side surfaces of the transparent member 94, such light does not reach the light-receiving surface. Consequently, stray light (i.e., diffuse reflection of light) can be eliminated, and thus optical properties can be enhanced.

With respect to the height (i.e., distance) from a mounting surface 62 of a base 60, the height of the upper surface of the transparent member 94 is larger than that of the upper surfaces of the dams 80, 80. Accordingly, in placing the semiconductor device 7 in an optical pickup module, the upper surface of the transparent member 94 that is parallel to the light-receiving surface of the semiconductor element 10 and has a large area can be easily used as a reference surface for the placement. In addition, accuracy in the placement in the optical pickup module can be easily enhanced. Further, the placement can be easily performed for a short period of time.

### —Method for Fabricating Semiconductor Device—

A method for fabricating a semiconductor device 7 according to this reference embodiment is now described. Description of process steps already described in the first embodiment is omitted or simplified.

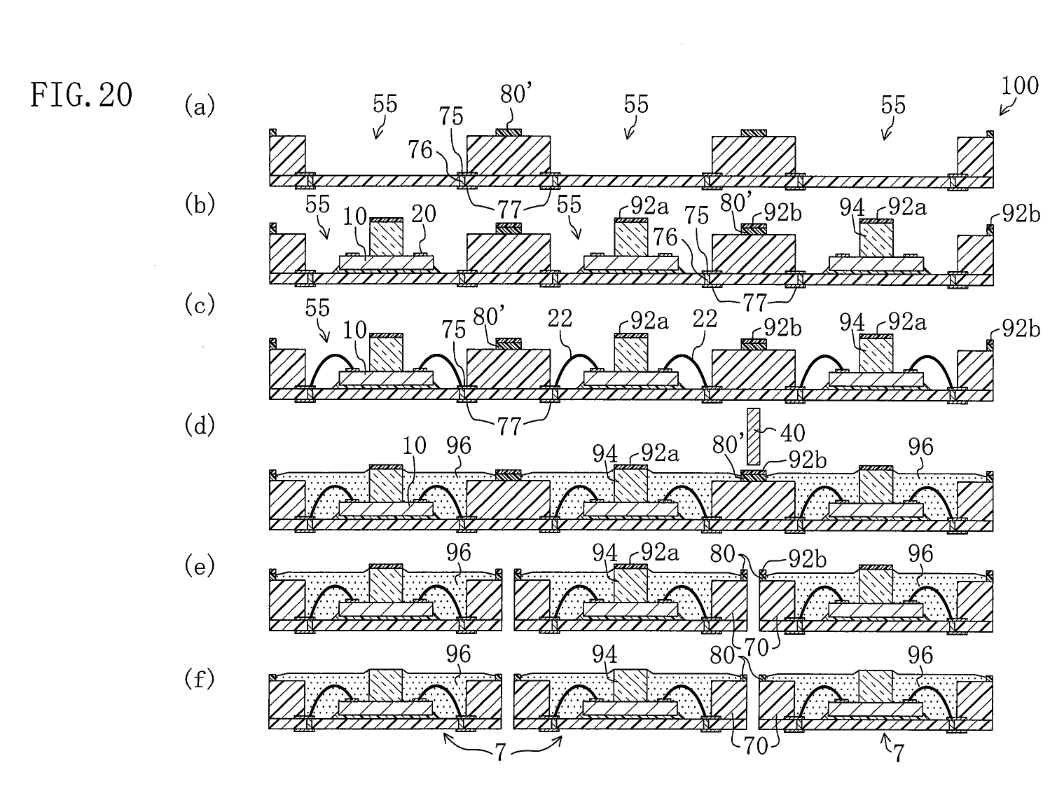

First, a package-assembled board 100 illustrated in FIG. 20(a) is prepared. This package-assembled board 100 is identical to that used in the first embodiment.

Next, a plurality of semiconductor elements 10 are sequentially placed on, and fixed to, the bottom surfaces of trenches 55, 55, . . . along the direction in which the trenches 55, 55, . . . extend. Then, transparent members 94 are placed on the light-receiving surfaces of the semiconductor elements 10, and are fixed with a transparent adhesive. At this time, protective sheets 92a are provided on the upper surfaces of the transparent members 94. Protective sheets 92b are then provided on the upper surfaces of the dams 80′. In this manner, a configuration as illustrated in FIG. 20(b) is obtained.

Then, electrode pads 20 of the semiconductor elements 10 are wire bonded to connection electrodes 75. In this manner, as illustrated in FIG. 20(c), the electrode pads 20 and the connection electrodes 75 are connected to each other by metal wires 22.

Thereafter, the trenches 55 are filled with an encapsulating resin 96. This filling may be achieved by potting or injection molding. At this time, the entire upper surfaces of the transparent members 94 and the upper surfaces of the dams 80′ are covered with the protective sheets 92a and 92b. This structure ensures that the upper surfaces of the transparent members 94 and the upper surfaces of the dams 80′ are not covered with the encapsulating resin 96 and are exposed. FIG. 20(d) shows a state in which the encapsulating resin 96 fills the trenches, and is cured.

Subsequently, the board is cut with a dicing saw 40 in such a manner that the board is divided into two at a middle portion of the dam 80′ between each adjacent two of the trenches 55, 55. The state after the division is shown in FIG. 20(e). In this manner, side wall surfaces are made flush with one another.

Then, the protective sheets 92a and 92b are peeled off from the transparent members 94 and the dams 80′, thereby obtaining a state illustrated in FIG. 20(f). Thereafter, adjacent ones of the semiconductor elements 10 arranged perpendicularly to the direction along which the trenches 55 extend are separated from each other by cutting. In this manner, individual semiconductor devices 7 are obtained. It should be noted that because of compression of the encapsulating resin 96 during curing, the upper surface of the encapsulating resin 96 is located several micrometers below the upper surfaces of the transparent members 94 and the upper surfaces of the dams 80.

As the semiconductor device 1 of the first embodiment, the semiconductor device 7 of this reference embodiment can also be made smaller in size than conventional semiconductor devices.

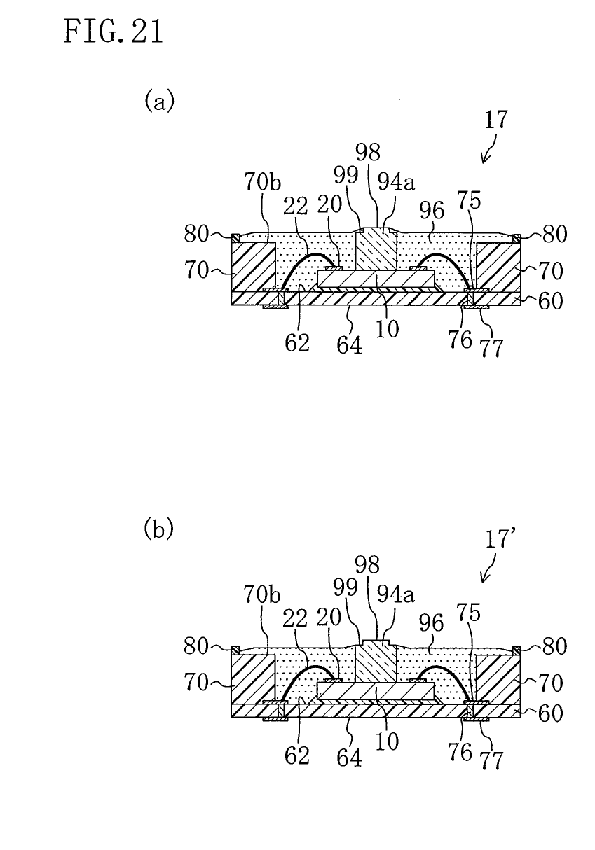

Further, the transparent members 94 may be modified to form semiconductor devices 17, 17′ including steps on external edge portions of upper surfaces, as illustrated in FIGS. 21(a) and 21(b). In FIG. 21(a), the upper surface of a transparent member 94a is stepped to have: a top surface 98 located in a middle portion of this upper surface and corresponding to the shape and size of the optical functional surface of a semiconductor element 10; and stepped surfaces 99 located below the top surface 98 at a distance corresponding to the steps. An encapsulating resin 96 covers the stepped surfaces 99, but does not cover the top surface 98. The presence of the stepped surfaces 99 in this manner ensures that the top surface 98 is not covered with the encapsulating resin 96, resulting in ensuring entering of necessary light into the optical functional surface of the semiconductor element 10, or resulting in efficient emission of light from the optical functional surface.

Alternatively, as illustrated in FIG. 21(b), none of stepped surfaces 99 and a top surface 98 of a semiconductor device 17′ may be covered with an encapsulating resin 96.

### Reference Embodiment 2

A semiconductor device according to a second reference embodiment differs from the semiconductor device 7 of the first reference embodiment only in that the dams 80 are removed from the semiconductor device 7. In the other aspects, the semiconductor device of the second reference embodiment is the same as that of the first reference embodiment, and thus only different aspects are now described.

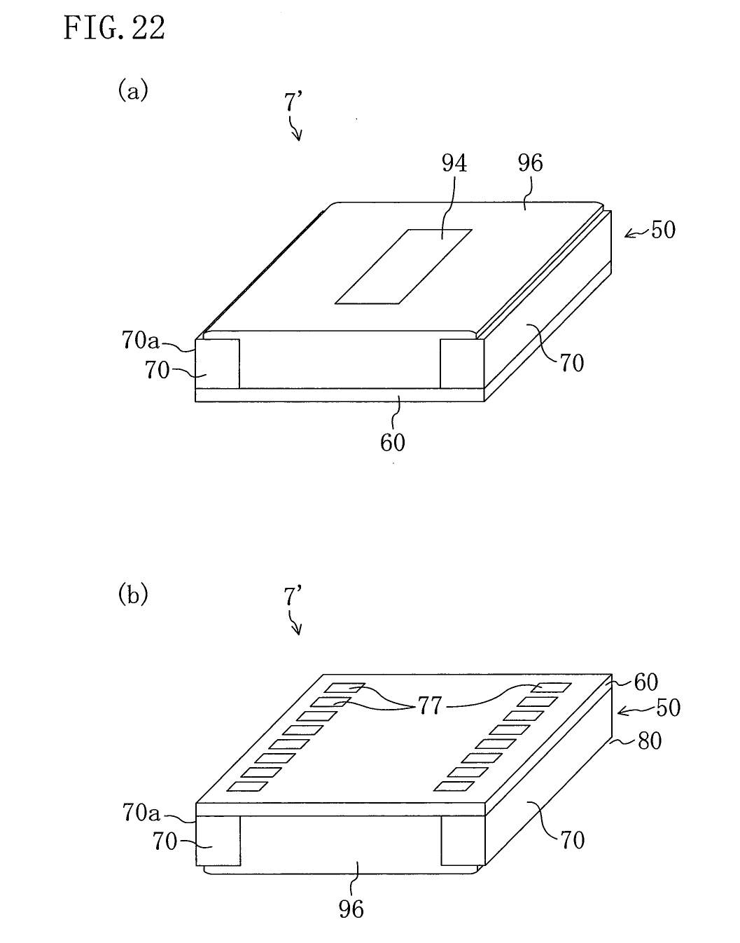

A semiconductor device 7′ according to this reference embodiment illustrated in FIG. 22 is fabricated by removing dams 80 after, or in the middle of, fabrication of the semiconductor device 7 of the first reference embodiment. Accordingly, the semiconductor device 7′ of this reference embodiment has a structure, a configuration, and a shape obtained by removing the dams 80 from the semiconductor device 7 of the first reference embodiment. Specifically, as in the semiconductor device 2 of the second embodiment, a trace of blockage by the dams 80 remains at end portions of an encapsulating resin 96 near external edges of first ribs 70.

In addition to the advantages of the first reference embodiment, the semiconductor device 7′ of this reference embodiment has an advantage of smooth assembly without being caught in incorporating the semiconductor device 7′ in an optical pickup module.

### Reference Embodiment 3

A semiconductor device according to a third reference embodiment is obtained by adding second ribs to the semiconductor device 7 of the first reference embodiment, and the other aspects of the third reference embodiment are the same as those in the first reference embodiment. A package employed in the third reference embodiment is the same as that employed in the third embodiment. Now, the third reference embodiment, particularly aspects thereof different from those of the first reference embodiment and the third embodiment, is described. The same aspects as those of the first reference embodiment and the third embodiment may be omitted in the following description.

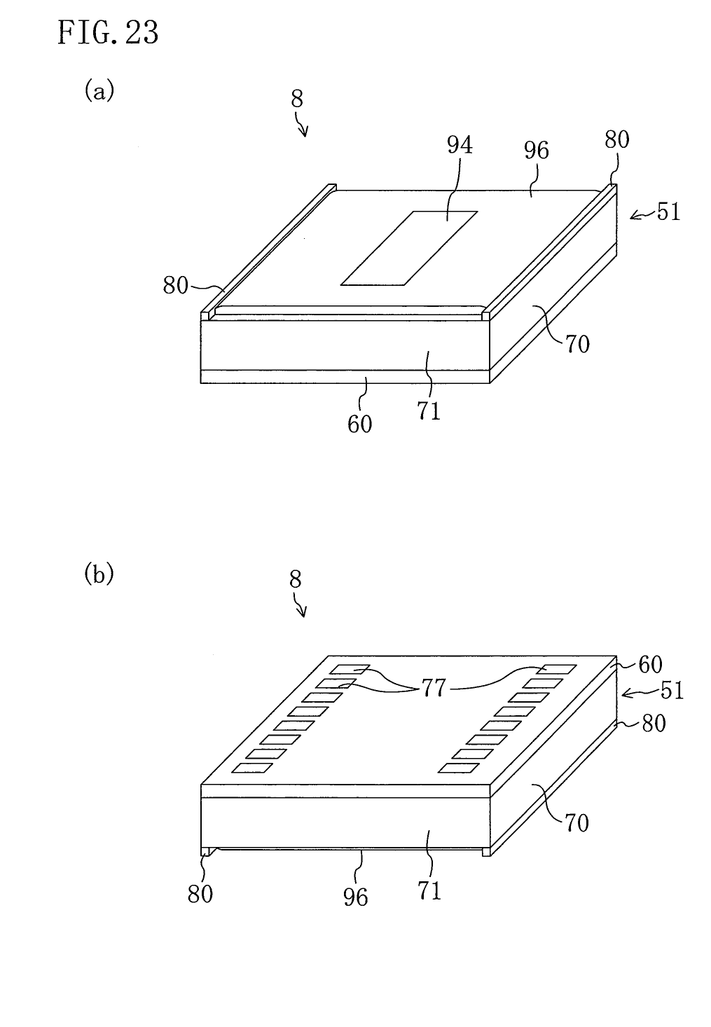

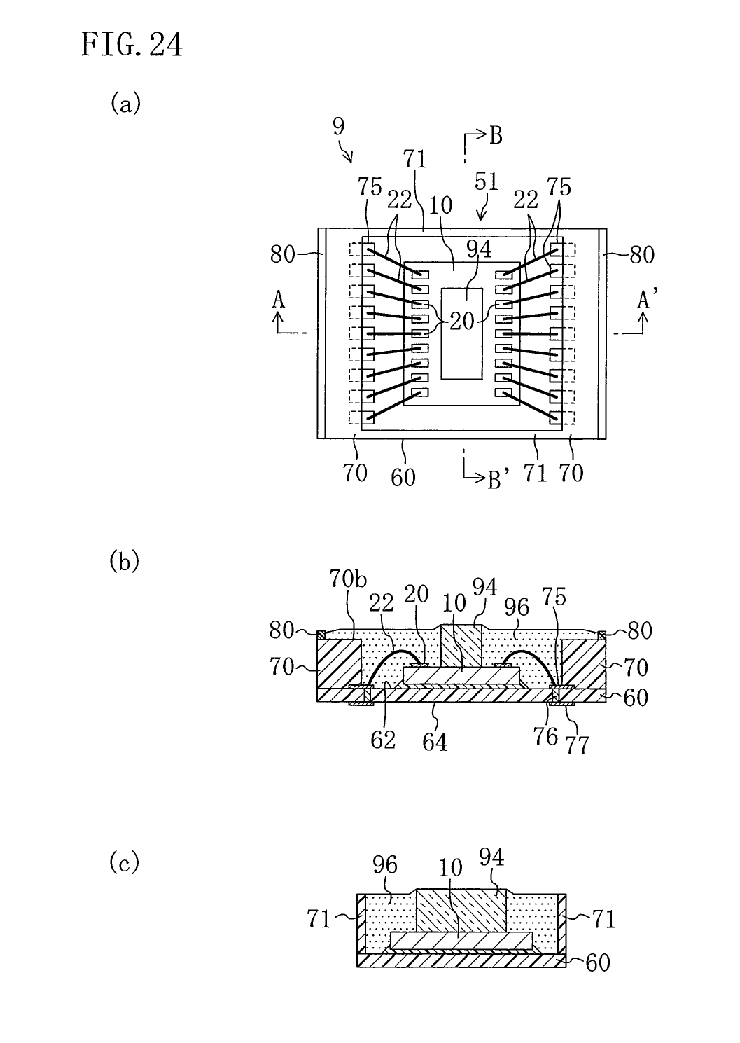

FIGS. 23(a) and 23(b) and FIGS. 24(a) through 24(c) illustrate a semiconductor device 8 according to this reference embodiment. In FIG. 24(a), an encapsulating resin 96 is not shown for convenience of description. In this reference embodiment, a package 51, a semiconductor element 10, dams 80, 80, first ribs 70, 70, and metal wires 22 are the same as those in the third embodiment, and a configuration for connecting connection electrodes 75 to external-connection portions 77 and a configuration for connecting a semiconductor element 10 to the connection electrodes 75 are also the same as those in the third embodiment.

In the semiconductor device 8 of this reference embodiment, second ribs 71, 71 are provided at side surfaces of the semiconductor device at which the encapsulating resin 96 is exposed in the semiconductor device 7 of the first reference embodiment, in such a manner that the second ribs 71, 71 cover the encapsulating resin 96 at these side surfaces.

The semiconductor device 8 of this reference embodiment has the same advantages as those of the semiconductor device 7 of the first reference embodiment.

### Reference Embodiment 4

A semiconductor device according to a fourth reference embodiment differs from the semiconductor device 8 of the third reference embodiment only in that the dams 80 are removed from the semiconductor device 8. In the other aspects, the semiconductor device of the fourth reference embodiment is the same as that of the third reference embodiment, and thus only different aspects are now described.

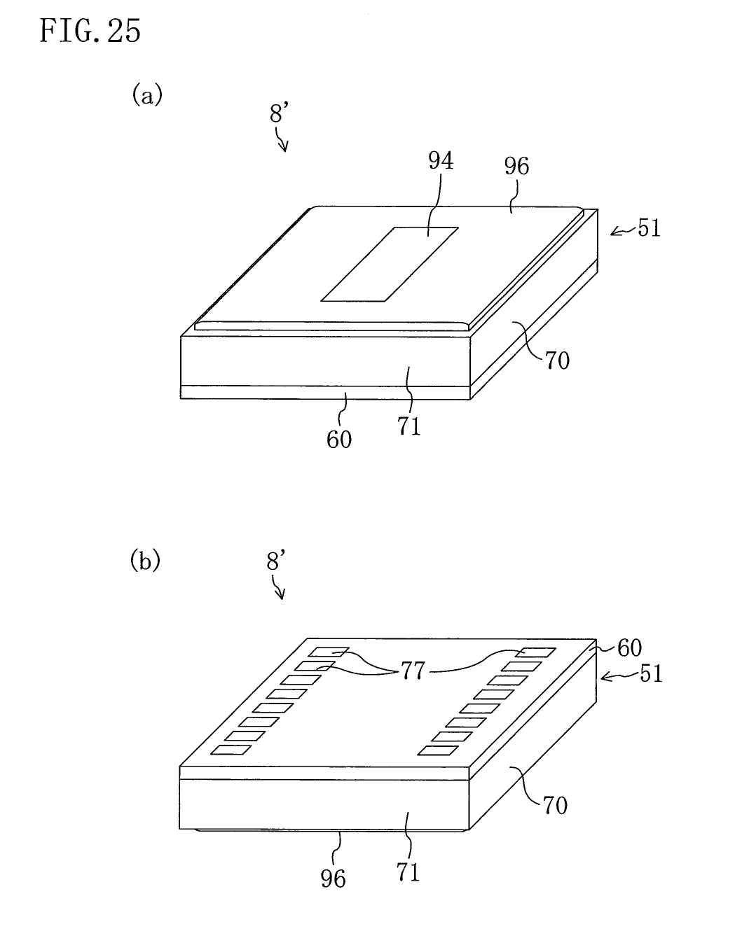

A semiconductor device 8′ according to this reference embodiment illustrated in FIG. 25 is fabricated by removing dams 80 after, or in the middle of, fabrication of the semiconductor device 8 of the third reference embodiment. Accordingly, the semiconductor device 8′ of this reference embodiment has a structure, a configuration, and a shape obtained by removing the dams 80 from the semiconductor device 8 of the third reference embodiment. Specifically, as in the semiconductor device 2 of the second embodiment, a trace of blockage by the dams 80 remains at end portions of an encapsulating resin 96 near external edges of first ribs 70.

In addition to the advantages of the third reference embodiment, the semiconductor device 8′ of this reference embodiment has an advantage of smooth assembly without being caught in incorporating the semiconductor device 8′ in an optical pickup module.

### Other Embodiment

The foregoing embodiments are merely examples of the present invention, and do not limit the present invention.

The external-connection portions may be provided on an area except for the non-mounting surface of the base. For example, the external-connection portions may be provided on the rib external side wall surfaces, or may be continuously provided from the mounting surface to the rib external side wall surfaces. The external-connection portions and the connection electrodes do not need to be connected by through electrodes provided in the ribs, and may be connected by wires provided along the side wall surfaces of the ribs.

The semiconductor element does not need to be a solid-state image sensor, and may be a photoreceiver such as a photocoupler or a light-emitting element such as an LED and a laser device. Further, the semiconductor element does not need to be an optical device, and may be a SAW device, an oscillator, a pressure sensor, an acceleration sensor, or a sound sensor, for example. In this case, the lid does not need to be transparent. Furthermore, the semiconductor element may be fabricated by MEMS.

In fabricating a semiconductor device including no second ribs as described in the first and second embodiments, a package-assembled board using a lattice member illustrated in FIG. 10 or 11 and a board may be employed. In this case, positions of the board at which individual semiconductor devices are separated are adjusted such that the second ribs do not remain.

### INDUSTRIAL APPLICABILITY

As described above, a semiconductor device according to the present invention can be miniaturized, and is useful as, for example, a photodetector for use in an optical pickup module.

1. A semiconductor device, comprising:
a semiconductor element; and
a package on which the semiconductor element is mounted, wherein
the package includes
a base which is substantially rectangular and has a mounting surface on which the semiconductor element is mounted and
first ribs respectively provided only on a pair of opposite external edges of the mounting surface and extending along the pair of opposite external edges,
a dam is provided on an upper surface of each of the first ribs, and extends along an external edge of the upper surface of the first rib,
an external edge portion of a lid covering the semiconductor element is placed on the upper surface of each of the first ribs, and is at a location separated from the dam and closer to the semiconductor element than the dam, and
the lid is bonded to the first ribs with an adhesive which is sandwiched between the lid and the dam.

2. The semiconductor device of claim 1, wherein the adhesive also adheres to a side surface of the lid facing the dam.

3. The semiconductor device of claim 1, wherein a side wall surface of each of the first ribs along the external edge of the mounting surface on which the first rib is provided is flush with an external side wall surface of the dam along the external edge of the upper surface of the first rib.

4. A semiconductor device, comprising:
a semiconductor element; and
a package on which the semiconductor element is mounted, wherein
the package includes
a base which is substantially rectangular and has a mounting surface on which the semiconductor element is mounted,
first ribs respectively provided on a pair of opposite external edges of the mounting surface and extending along the pair of opposite external edges, and
second ribs respectively provided on another pair of opposite external edges of the mounting surface and extending along the another pair of opposite external edges,
a dam is provided on an upper surface of each of the first ribs, and extends along an external edge of the upper surface of the first rib,
an external edge portion of a lid covering the semiconductor element is placed on the upper surface of each of the first ribs, and is at a location separated from the dam and closer to the semiconductor element than the dam,
the lid is bonded to the first ribs with an adhesive which is sandwiched between the lid and the dam, and
a width of each of the second ribs orthogonal to the another pair of opposite external edges is smaller than a width of each of the first ribs orthogonal to the pair of external edges.

5. The semiconductor device of claim 4, wherein the adhesive also adheres to a side surface of the lid facing the dam.

6. The semiconductor device of claim 4, wherein a side wall surface of each of the first ribs along the external edge of the mounting surface on which the first rib is provided is flush with an external side wall surface of the dam along the external edge of the upper surface of the first rib.

7. The semiconductor device of claim 4, wherein the lid is bonded to the second ribs with the adhesive.

8. A semiconductor device, comprising:
a semiconductor element; and
a package on which the semiconductor element is mounted, wherein
the package includes
a base which is substantially rectangular and has a mounting surface on which the semiconductor element is mounted and
first ribs respectively provided only on a pair of opposite external edges of the mounting surface and extending along the pair of opposite external edges,
an external edge portion of a lid covering the semiconductor element is placed on an upper surface of each of the first ribs,
the lids is bonded to the first ribs with an adhesive,
a fillet is formed of the adhesive on a side surface of the lid located on each of the first ribs, and
a trace of blockage remains at an end of the fillet opposite an end of the fillet facing the side surface of the lid.

9. A semiconductor device, comprising:
a semiconductor element; and
a package on which the semiconductor element is mounted, wherein
the package includes
a base which is substantially rectangular and has a mounting surface on which the semiconductor element is mounted,
first ribs respectively provided on a pair of opposite external edges of the mounting surface and extending along the pair of opposite external edges,
second ribs respectively provided on another pair of opposite external edges of the mounting surface and extending along the another pair of opposite external edges,
an external edge portion of a lid covering the semiconductor element is placed on an upper surface of each of the first ribs,
the lids is bonded to the first ribs with an adhesive,
a fillet is formed of the adhesive on a side surface of the lid located on each of the first ribs,
a trace of blockage remains at an end of the fillet opposite an end of the fillet facing the side surface of the lid, and
a width of each of the second ribs orthogonal to the another pair of opposite external edges is smaller than a width of each of the first ribs orthogonal to the pair of external edges.

10. The semiconductor device of claim 9, wherein the lid is bonded to the second ribs with the adhesive.

11. A method for fabricating a semiconductor device including a semiconductor element and a package on which the semiconductor element is mounted, the method comprising the steps of:
preparing a package-assembled board including
a plurality of parallel trenches, and
dams respectively located on middle portions of upper surfaces of side walls of the trenches and extending along the trenches,
placing a plurality of semiconductor elements in each of the trenches in a direction along which the trench extends;
continuously applying an adhesive, along the trenches, onto portions of the upper surfaces of the side walls of the trenches located between the dams and the trenches,
X: placing an external edge portion of a lid on the adhesive such that the lid covers each of the semiconductor elements,
hardening the adhesive, and
Y: cutting, along the trenches, the package-assembled board at a middle portion thereof between each adjacent two of the trenches, thereby dividing the package-assembled board.

12. The method of claim 11, wherein in step Y, parts of the dams are also cut.

13. The method of claim 11, wherein in step X, the adhesive adheres to a side surface of the lid, and forms a fillet.

14. A method for fabricating a semiconductor device including a semiconductor element and a package on which the semiconductor element is mounted, the method comprising the steps of:
preparing a package-assembled board including
a plurality of recesses arranged in rows and columns, and
dams respectively located on middle portions between adjacent rows of the recesses and extending along the rows;
placing a plurality of semiconductor elements in each of the recesses;
continuously applying an adhesive, along the dams, onto portions between the rows of the recesses and neighboring the dams;
X: placing an external edge portion of a lid on the adhesive such that the lid covers each of the semiconductor elements;
hardening the adhesive; and
Z: cutting the package-assembled board at a middle portion thereof between each adjacent two of the recesses along the rows of the recesses, thereby dividing the package-assembled board.

15. The method of claim 14, wherein a distance between each adjacent columns of the recesses is smaller than or equal to a distance between each adjacent rows of the recesses.

16. The method of claim 14, wherein in step Z, parts of the dams are also cut.

17. The method of claim 14, wherein in step X, the adhesive adheres to a side surface of the lid, and forms a fillet.

18. The method of claim 14, further comprising the step of removing the dams, after the step of hardening the adhesive.

19. An optical pickup module, comprising:
the semiconductor device recited in claims 1, 4, 8, and 9;
a laser module; and
a beam splitter, wherein
the lid is made of a transparent material, and
the semiconductor element included in the semiconductor device is a photoreceiver.

20. The optical pickup module of claim 19, further comprising a mirror and an objective lens.

21. The optical pickup module of claim 19, wherein the optical pickup module is placed under an information-recording surface of an optical disk, and
a direction along which the first ribs extend is substantially perpendicular to the information-recording surface.

22. The optical pickup module of one of claims 19 to 21 claim 19, wherein
the laser module includes:
a blue-violet laser device configured to emit light having a peak wavelength ranging from 385 nm to 425 nm, both inclusive; and
a dual-wavelength laser device configured to emit light having a peak wavelength ranging from 630 nm to 670 nm, both inclusive, and light having a peak wavelength ranging from 760 nm to 800 nm, both inclusive.
